(19) United States
(12) Patent Application Publication
(10) Pub. No.: US 2022/0380505 A1
(43) Pub. Date: Dec. 1, 2022

(54) COMPOSITION FOR FORMING IMPRINT PATTERN, CURED SUBSTANCE, IMPRINT PATTERN PRODUCING METHOD, AND METHOD FOR MANUFACTURING DEVICE

(71) Applicant: FUJIFILM Corporation, Tokyo (JP)

(72) Inventor: Akihiro HAKAMATA, Haibara-gun (JP)

(73) Assignee: FUJIFILM Corporation, Tokyo (JP)

(21) Appl. No.: 17/874,727

(22) Filed: Jul. 27, 2022

Related U.S. Application Data
(63) Continuation of application No. PCT/JP2021/002794, filed on Jan. 27, 2021.

(30) Foreign Application Priority Data
Jan. 31, 2020 (JP) 2020-015247

(51) Int. Cl. C08F 222/10; C08F 2/50; G03F 7/00

(52) U.S. Cl. CPC C08F 222/102; C08F 222/1025; C08F 2/50; G03F 7/0002

(57) ABSTRACT

Provided are a composition for forming an imprint pattern, containing a polymerizable compound, a polymerization initiator, and a dye, in which the dye is a compound which has no metal element in a chemical structure; a cured substance consisting of the composition for forming an imprint pattern; an imprint pattern producing method using the composition for forming an imprint pattern; and a method for manufacturing a device, including the imprint pattern producing method.

### CROSS-REFERENCE TO RELATED APPLICATIONS

This application is a Continuation of PCT International Application No. PCT/JP2021/002794 filed on Jan. 27, 2021, which claims priority under 35 § 119(a) to Japanese Patent Application No. 2020-015247 filed on Jan. 31, 2020. Each of the above application(s) is hereby expressly incorporated by reference, in its entirety, into the present application.

### BACKGROUND OF THE INVENTION

### 1. Field of the Invention

The present invention relates to a composition for forming an imprint pattern, a cured substance, an imprint pattern producing method, and a method for manufacturing a device.

### 2. Description of the Related Art

An imprinting method is a technique in which a fine pattern is transferred to a material by pressing a metal mold (generally also called a mold or a stamper) on which a pattern is formed. The imprinting method enables simple and precise production of a fine pattern, and thus is expected to be applied in various fields, such as a precision processing field for semiconductor integrated circuits, in recent years. In particular, a nanoimprint technique for forming a fine pattern of a nano-order level is attracting attention.

As a composition used in the imprinting method, for example, JP2009-117513A discloses a resin composition for a light or thermocurable nanoimprint having dry etching resistance, which contains a metal-containing complex salt dye and an organic solvent, in which the dye is dissolved in the organic solvent.

In addition, WO2018/180477A discloses a colored film having a concavo-convex structure on its surface, in which an average distance between adjacent convex portions in the concavo-convex structure is 1500 nm or less, a standard deviation of the distance between the adjacent convex portions is 10 to 300 nm, and 95.0% or more of the convex portions satisfy a specific expression.

### SUMMARY OF THE INVENTION

As the imprinting method, methods called a thermal imprinting method and a curable imprinting method have been proposed depending on a transfer method. In the thermal imprinting method, for example, a mold is pressed against a thermoplastic resin heated to a temperature equal to or higher than a glass transition temperature (hereinafter, referred to as a “Tg” in some cases), the thermoplastic resin is cooled, and then the mold is released to form a fine pattern. In this method, various materials can be selected, but there are problems in that it is difficult to form a fine pattern, such as the need for high pressure during pressing and the deterioration of dimensional accuracy due to heat contraction.

In the curable imprinting method, for example, a composition for forming an imprint pattern is cured by light or heat in a state in which a mold is pressed against the composition for forming an imprint pattern, and then the mold is released. Since it is imprinted on an uncured material, it is possible to omit part or all of high-pressure addition and high-temperature heating, and it is possible to easily produce a fine pattern. Moreover, since a dimensional change before and after curing is small, there is also an advantage that a fine pattern can be formed with high accuracy.

Examples of the curable imprinting method include a method in which the composition for forming an imprint pattern is applied to a substrate (if necessary, being performed an adhesion treatment such as forming an adhesion layer), and then a mold formed of a light-transmitting material such as quartz is pressed against the substrate. The composition for forming an imprint pattern is cured by light irradiation in a state where the mold is pressed, and then the mold is released to produce a cured substance to which a desired pattern is transferred.

In a case where the mold is released after the composition for forming an imprint pattern is cured by light or heat in this way, there is a request to visually recognize whether or not the composition for forming an imprint pattern is peeled off from the mold.

Moreover, the same mold can be used repeatedly in the imprinting method, and in such a case, there is a request to suppress an occurrence of defects in the mold. In the present invention, in a case where the mold is used repeatedly a plurality of times, the suppression of the occurrence of defects in the mold is also referred to as that “mold durability is excellent”.

An object of the present invention is to provide a composition for forming an imprint pattern, in which a peeling from the mold can be visually recognized and a mold durability is excellent, a cured substance formed of the composition for forming an imprint pattern, an imprint pattern producing method using the composition for forming an imprint pattern, and a method for manufacturing a device, which includes the imprint pattern producing method.

Typical embodiments of the present invention are shown below.

<1> A composition for forming an imprint pattern, comprising:

a polymerizable compound;

a polymerization initiator; and

a dye,

in which the dye is a compound which has no metal element in a chemical structure.

<2> The composition for forming an imprint pattern according to <1>,

in which a maximum value of a molar absorption coefficient of the dye in an acetonitrile solution, a methanol solution, a chloroform solution, and an aqueous solution in a wavelength range of 400 to 800 nm is 50 L/(mol·cm) or greater.

<3> The composition for forming an imprint pattern according to <1> or <2>,

in which the dye is a compound which has a maximal absorption in a wavelength range of 400 to 800 nm in at least one of an acetonitrile solution, a methanol solution, a chloroform solution, and an aqueous solution.

<4> The composition for forming an imprint pattern according to any one of <1> to <3>,

in which the dye includes at least one compound selected from the group consisting of an azo-based compound, an anthraquinone-based compound, and a carbonium-based compound.

<5> The composition for forming an imprint pattern according to any one of <1> to <4>,

in which a content of the dye is 0.001% to 20.0% by mass with respect to a total solid content of the composition for forming an imprint pattern.

<6> The composition for forming an imprint pattern according to any one of <1> to <5>,

in which the polymerization initiator is a photopolymerization initiator.

<7> The composition for forming an imprint pattern according to any one of <1> to <6>, further comprising:

a release agent.

<8> The composition for forming an imprint pattern according to any one of <1> to <7>, further comprising:

a solvent,

in which a content of the solvent is 90.0% to 99.0% by mass with respect to a total mass of the composition for forming an imprint pattern.

<9> The composition for forming an imprint pattern according to any one of <1> to 7>,

in which the composition for forming an imprint pattern does not include a solvent, or

the composition for forming an imprint pattern includes a solvent and a content of the solvent is greater than 0% by mass and lower than 5% by mass with respect to a total mass of the composition for forming an imprint pattern.

<10> The composition for forming an imprint pattern according to any one of <1> to <9>,

in which a total content of a metal atom and a metal ion is 0.1% by mass or lower with respect to a total solid content of the composition for forming an imprint pattern.

<11> The composition for forming an imprint pattern according to any one of <1> to <10>,

in which a content of an inorganic compound is 1% by mass or lower with respect to a total solid content of the composition for forming an imprint pattern.

<12> The composition for forming an imprint pattern according to any one of <1> to <11>,

in which a content of a salt compound is 1% by mass or lower with respect to a total solid content of the composition for forming an imprint pattern.

<13> A cured substance obtained by curing the composition for forming an imprint pattern according to any one of <1> to <12>.

<14> An imprint pattern producing method comprising:

an applying step of applying the composition for forming an imprint pattern according to any one of <1> to <12> to a member to be applied, which is selected from the group consisting of a support and a mold;

a contact step of contacting a member which is not selected as the member to be applied from the group consisting of the support and the mold with the composition for forming an imprint pattern as a contact member;

a curing step of forming a cured substance with the composition for forming an imprint pattern; and

a peeling step of peeling off the cured substance from the mold.

<15> The imprint pattern producing method according to <14>, further comprising:

a step of evaluating a transparency of the mold using a visible light having a wavelength at which the dye has an absorption after the peeling step.

<16> The imprint pattern producing method according to <14> or <15>, in which the support is a member including a closely adhesive layer on a surface on a side to which the composition for forming an imprint pattern is applied.

<17> A method for manufacturing a device, comprising:

the imprint pattern producing method according to any one of <14> to <16>.

According to the present invention, a composition for forming an imprint pattern, in which a peeling from the mold can be visually recognized and a mold durability is excellent, a cured substance formed of the composition for forming an imprint pattern, an imprint pattern producing method using the composition for forming an imprint pattern, and a method for manufacturing a device, which includes the imprint pattern producing method, are provided.

### DESCRIPTION OF THE PREFERRED EMBODIMENTS

Hereinafter, representative embodiments of the present invention will be described. Respective constituent elements will be described based on the representative embodiments for convenience, but the present invention is not limited to such embodiments.

In the present specification, a numerical range expressed using the term “to” means a range which includes the preceding and succeeding numerical values of “to” as a lower limit value and an upper limit value, respectively.

In the present specification, the term “step” is meant to include not only an independent step, but also a step which cannot be clearly distinguished from other steps as long as an intended action of the step is achieved.

In the present specification, with regard to a group (atomic group), in a case where the group (atomic group) is described without specifying whether the group (atomic group) is substituted or unsubstituted, the description means that the group (atomic group) includes both a group (atomic group) having no substituent and a group having a substituent. For example, in a case where a group is simply described as an “alkyl group”, the description means that the alkyl group includes both an alkyl group having no substituent (unsubstituted alkyl group) and an alkyl group having a substituent (substituted alkyl group).

In the present specification, unless otherwise specified, “exposure” is meant to include not only drawing using light but also drawing using particle rays such as electron beams and ion beams. Examples of energy rays used for the drawing include actinic rays such as a bright line spectrum of a mercury lamp, far ultraviolet rays typified by an excimer laser, extreme ultraviolet rays (EUV light), and X-rays, and particle rays such as electron beams and ion beams.

In the present specification, “(meth)acrylate” means both “acrylate” and “methacrylate” or either of them, “(meth)acryl” means both “acryl” and “methacryl” or either of them, and “(meth)acryloyl” means both “acryloyl” and “methacryloyl” or either of them.

In the present specification, a solid content in a composition means components other than a solvent, and a content (concentration) of the solid content in the composition is represented by the mass percentage of the components other than the solvent with respect to the total mass of the composition, unless otherwise specified.

In the present specification, a temperature is 23° C., an atmospheric pressure is 101,325 Pa (1 atm), and a relative humidity is 50% RH, unless otherwise specified.

In the present specification, a weight-average molecular weight (Mw) and a number-average molecular weight (Mn) are each expressed as a value in terms of polystyrene according to gel permeation chromatography (GPC measurement), unless otherwise specified. The weight-average molecular weight (Mw) and the number-average molecular weight (Mn) can be determined, for example, by using HLC-8220 (manufactured by TOSOH CORPORATION), and, as columns, GUARD COLUMN HZ-L, TSKgel Super HZM-M, TSKgel Super HZ4000, TSKgel Super HZ 3000, and TSKgel Super HZ2000 (manufactured by TOSOH CORPORATION). Moreover, the measurement is performed using tetrahydrofuran (THF) as an eluent, unless otherwise specified. Furthermore, for the detection in the GPC measurement, a detector of ultraviolet rays (UV rays) having a wavelength of 254 nm is used, unless otherwise specified.

In the present specification, regarding a positional relationship of respective layers constituting a laminate, in a case where there is a description of “upper” or “lower”, another layer may be on an upper side or a lower side of a reference layer among a plurality of layers of interest. That is, a third layer or element may be further interposed between the reference layer and the other layer, and the reference layer and the other layer are not necessary to be in contact with each other. Moreover, unless otherwise specified, in a case where a direction in which layers are stacked on a substrate is referred to as “upward” or there is a photosensitive layer, a direction from the substrate to the photosensitive layer is referred to as “upward”, and the opposite direction is referred to as “downward”. Furthermore, such setting of upward and downward directions is for convenience in the present specification, and in a practical aspect, the “upward” direction in the present specification may be different from a vertically upward direction.

In the present specification, “imprint” preferably refers to transfer of a pattern with a size of 1 nm to 10 mm, and more preferably refers to transfer (nanoimprint) of a pattern with a size of about 10 nm to 100 μm.

### Composition for Forming Imprint Pattern

A composition for forming an imprint pattern according to an embodiment of the present invention contains a polymerizable compound, a polymerization initiator, and a dye, in which the dye is a compound which has no metal element in a chemical structure.

Hereinafter, the dye that is a compound having no metal element in a chemical structure is also referred to as a “specific dye”.

In a case where the composition for forming an imprint pattern according to the embodiment of the present invention is used, the peeling of the composition for forming an imprint pattern from a mold can be visually recognized, and a mold durability is excellent.

In the present invention, the fact that the peeling of the composition for forming an imprint pattern from the mold can be visually recognized refers to that, after the composition for forming an imprint pattern is peeled off from the mold, it can be confirmed whether or not the composition for forming an imprint pattern remains by checking the mold visually or by a unit such as a magnifying glass and an optical microscope. The above-described confirmation may be performed visually or by using a unit such as a magnifying glass and an optical microscope, but it is preferably performed visually or by using a magnifying glass, and it is more preferably performed visually.

The mechanism for obtaining the above-described effect is not clear, but is presumed as follows.

The composition for forming an imprint pattern according to the embodiment of the present invention includes the specific dye. Therefore, it is considered that it is possible to visually recognize the above-described peeling.

In addition, the specific dye used in the present invention includes no metal element in the chemical structure.

Therefore, in a case where the mold is used repeatedly, it is considered that an accumulation of metal elements included in the composition for forming an imprint pattern reduces a damage to the mold, thereby improving the mold durability.

Here, in JP2009-117513A and WO2018/180477A, there is no discloser or suggestion that the above-described peeling can be visually recognized and the mold durability is improved by using such a dye.

Hereinafter, details of each component included in the composition for forming an imprint pattern according to the embodiment of the present invention will be described.

### Specific Dye

The composition for forming an imprint pattern according to the embodiment of the present invention includes the specific dye.

The specific dye is a dye which includes no metal element in the chemical structure.

That is, a dye including a metal complex structure is not included in the specific dye.

The metal element refers to an element other than a non-metal element and a semimetal element, and examples thereof include copper, zinc, aluminum, chromium, cobalt, nickel, and iron.

The specific dye may include a semimetal element such as silicon, boron, and germanium in the chemical structure, but from the viewpoint of mold durability, it is preferable not to include the semimetal element.

In the present invention, the dye is a compound which absorbs light having at least a part of a wavelength range of 400 to 800 nm, and refers to a compound dissolved in the composition.

The dye may be dissolved in at least one component included in the composition, for example, may be dissolved in a polymerizable compound or dissolved in a solvent described later, but it is preferable to be dissolved in a solvent.

By using a dye, compared with a case of using an insoluble compound in the composition, such as a pigment, a shape of the obtained imprint pattern is excellent, and for example, since a component used for dispersion, such as a dispersing agent, is not required, there are advantages such as excellent strength of the obtained imprint pattern.

### Molar Absorption Coefficient

The maximum value of a molar absorption coefficient of the specific dye in an acetonitrile solution, a methanol solution, a chloroform solution, and an aqueous solution in a wavelength range of 400 to 800 nm is preferably 50 L/(mol·cm) or greater, more preferably 5,000 L/(mol·cm) or greater, still more preferably 7,000 L(mol·cm) or greater, and particularly preferably 10,000 L/(mol·cm) or greater. The upper limit of the above-described molar absorption coefficient is not particularly limited, but may be, for example, 200,000 U(mol·cm) or lower.

The molar absorption coefficient is a value corresponding to an absorbance in a case where a dye concentration is set to 1 mol/L and an optical path length is set to 1 cm.

The maximum value of the molar absorption coefficient of the specific dye in an acetonitrile solution, a methanol solution, a chloroform solution, and an aqueous solution in a wavelength range of 400 to 800 nm refers to a maximum value of an absorbance in the above-described three kinds of solutions in the wavelength range of 400 to 800 nm and a maximum value among three molar absorption coefficients calculated from the dye concentration. The above-described molar absorption coefficient is measured, for example, by the method described in Examples described later.

### Maximal Absorption Wavelength

It is preferable that the specific dye is a compound which has a maximal absorption in a wavelength range of 400 to 800 nm in at least one of an acetonitrile solution, a methanol solution, a chloroform solution, and an aqueous solution.

Moreover, the specific dye is preferably a compound having a maximal absorption in a wavelength range of 400 to 550 nm, and more preferably a compound having a maximal absorption in a wavelength range of 400 to 500 nm.

In a case where the specific dye is a compound having a maximal absorption in the above-described range, the composition for forming an imprint pattern according to the embodiment of the present invention is preferably handled under yellow light or red light to prevent unintended reactions.

Here, in a case where the specific dye is a compound having a maximal absorption at 400 to 550 nm (preferably 400 to 500 nm), the absorption to the yellow light or the red light is small, and even in a case where the composition is attached to a wall or the like of a container, the composition inside the container can be easily observed. As a result, for example, there is an advantage that a remaining amount of the composition in the container can be easily confirmed.

### Compound Type

Examples of the specific dye include a pyrazole azo compound, a pyromethene compound, an anilinoazo compound, a triphenylmethane compound, an anthraquinone compound, a benzylidene compound, an oxonol compound, a pyrazolotriazole azo compound, a pyridone azo compound, a cyanine compound, a phenothiazine compound, and a pyrrolopyrazole azomethine compound. Moreover, a coloring agent multimer may be used as the dye. Furthermore, a polymerizable dye having a polymerizable group in a molecule may be used, and examples of a commercially available product thereof include RDW series manufactured by FUJIFILM Wako Pure Chemical Corporation.

Among them, the specific dye preferably includes at least one compound selected from the group consisting of an azo-based compound, an anthraquinone-based compound, and a carbonium-based compound.

The azo-based compound is not particularly limited as long as it has an azo group as a chromophore and does not include a metal element in the chemical structure, and examples thereof include a monozao dye, a polyazo dye (a disazo dye, a trisazo dye, a tetrakisazo dye, and the like), an azo dye which is a diallyl urea derivative, an azo dye which is a diallylamine derivative, a stillbene azo dye, a thiazolc azo dye, and an azo dye having a cyanuric ring.

Specific examples thereof include Solvent Yellow 2, Solvent Yellow 4, Solvent Yellow 56, and Solvent Orange 7.

The anthraquinone-based compound is not particularly limited as long as it has an anthraquinone structure and does not include a metal element in the chemical structure, and examples thereof include an anthraquinone-based compound having an organic amine structure.

Specific examples thereof include Solvent Blue 35, Solvent Blue 59, Solvent Blue 104, Solvent Blue 112, Solvent Violet 13, and Solvent Green 3.

The carbonium-based compound is not particularly limited as long as it has a carbonium ion in a conjugated double bond and does not include a metal element in the chemical structure, and examples thereof include a diphenylmethylium dye, a triphenylmethylium dye, a xanthene dye, and an acridine dye.

Specific examples thereof include Solvent Yellow 93, Solvent Red 49, and RDW-R60 (manufactured by FUJIFILM Wako Pure Chemical Corporation).

The specific dye is preferably a compound which does not act as a sensitizer for a polymerization initiator described later.

Specifically, the action as a sensitizer refers to an action that a generation of polymerization initiation species from the polymerization initiator, such as that the specific dye absorbs light or heat energy and exchanges the energy with electrons or the like with the polymerization initiator, and that the specific dye is excited to transfer energy to the polymerization initiator.

### Content

A content of the specific dye is preferably 0.001% to 20,0% by mass with respect to the total solid content of the composition for forming an imprint pattern. The lower limit value of the content is preferably 0.1% by mass or greater, more preferably 0.5% by mass or greater, and still more preferably 1% by mass or greater. The upper limit value thereof is preferably 20.0% by mass or lower and more preferably 15% by mass or lower. In a case where the content is 0.001% by mass or greater, a visibility of the peeling of the composition from the mold is good. In addition, in a case of being 20.0% by mass or lower, an elastic modulus of a pattern forming, layer formed by the composition for forming an imprint pattern is appropriate, and a resolution is excellent.

The composition for forming an imprint pattern according to the embodiment of the present invention may contain one kind of the specific dye alone, or may contain two or more kinds thereof. In a case where two or more kinds thereof are contained, it is preferable that the total amount of the specific dyes contained in the composition for forming an imprint pattern is within the above-described range.

### Polymerizable Compound

The composition for forming an imprint pattern according to the embodiment of the present invention includes a polymerizable compound. The polymerizable compound is preferably a radically polymerizable compound.

### Polymerizable Group

The type of the polymerizable group included in the polymerizable compound is not particularly specified, and examples thereof include a group having an ethylenically unsaturated group and a cyclic ether group (an epoxy group, a glycidyl group, and an oxetanyl group). Among them, a group having an ethylenically unsaturated group is preferable. Examples of the group having an ethylenically unsaturated group include a (meth)acryloyl group, a (meth)acryloyloxy group, a (meth)acryloylamino group, a vinyl group, a vinyloxy group, an allyl group, and a vinylphenyl group. Among them, a (meth)acryloyl group or a (meth)acryloyloxy group is more preferable, and an acryloyl group or an acryloyloxy group is still more preferable. The polymerizable group defined here is referred to as Qp.

### Specific Polymerizable Compound

The polymerizable compound is not particularly limited, but a compound which has an absorption coefficient A of 1.8 L(g·cm) or lower, which will be described later, and has a weight-average molecular weight of 800 or more is preferable.

Hereinafter, the polymerizable compound which has an absorption coefficient A of 1.8 L(g·cm) or lower and has a weight-average molecular weight of 800 or more is referred to as a “specific polymerizable compound”.

Examples of the specific polymerizable compound include a compound (silicon-containing compound) containing a silicon atom (Si), a compound (ring-containing compound) containing a cyclic structure, and a dendrimer-type compound, and a silicon-containing compound or a ring-containing compound is preferable and a silicon-containing compound is more preferable.

In addition, the composition for forming an imprint pattern according to the embodiment of the present invention may contain only other polymerizable compounds described later without containing the specific polymerizable compound, or may contain only other polymerizable compounds described later in addition to the specific polymerizable compound.

### Maximum Value of Absorption Coefficient A

In the present invention, the maximum value of an absorbance of the specific polymerizable compound in an acetonitrile solution per unit mass in a wavelength range of 250 to 400 nm is referred to as the “absorption coefficient A”.

The maximum value of the absorption coefficient A of the specific polymerizable compound is 1.8 L/(g·cm) or lower, preferably 1.5 L/(g·cm) or lower, more preferably 1.2 1.1(g·cm) or lower, and still more preferably 1.0 L/(g·cm) or lower. In a case where a higher degree of translucency is required, the above-described absorption coefficient A is preferably 0.8 L/(g·cm) or lower, more preferably 0.5 L/(g·cm) or lower, still more preferably 0.2 L/(g·cm) or lower, and even more preferably lower than 0.01 L/(g·cm). The lower limit value thereof is not particularly limited, but 0.0001. L/(g·cm) or greater is preferable. In the composition according to the embodiment of the present invention, in a case where the absorption coefficient A is set to the above-described upper limit value or lower, curing properties of a deep portion of the pattern are improved and the resolution of the pattern is excellent.

### Weight-Average Molecular Weight

A weight-average molecular weight of the specific polymerizable compound is 800 or more, preferably 1,000 or more, more preferably 1,500 or more, and still more preferably more than 2,000. The upper limit of the weight-average molecular weight is not particularly specified, but for example, 100,000 or less is preferable, 50,000 or less is more preferable, 10,000 or less is still more preferable, 8,000 or less is even more preferable, 5,000 or less is even still more preferable, 3,500 or less is particularly preferable, and 3,000 or less is more particularly preferable. By setting the molecular weight to the above-described lower limit value or more, a volatility of the compound is suppressed, and characteristics of the composition or a coating film are stabilized. Moreover, good viscosity for maintaining a morphology of the coating film can be ensured. Further, it is possible to realize good releasability of the film by complementing the effect of suppressing a release agent to a small amount. By setting the molecular weight to the above-described upper limit value or less, it is easy to secure a low viscosity (fluidity) required for pattern filling, which is preferable.

### Silicon-Containing Compound

Examples of the silicon-containing compound include a compound having a silicone skeleton. Specific examples thereof include a compound having at least one of a D-unit siloxane structure represented by Formula (S1) or a T-unit siloxane structure represented by Formula (S2).

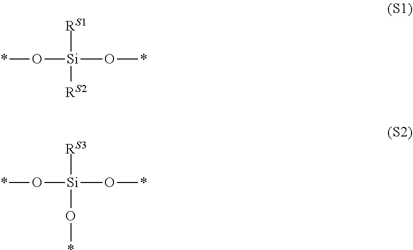

In Formula (S1) or Formula (S2), R^{S1} to R^{S3} each independently represent a hydrogen atom or a monovalent substituent, and *'s each independently represent a bonding site with other structures.

R^{S1} to R^{S3} are each independently preferably a monovalent substituent.

As the above-described monovalent substituent, an aromatic hydrocarbon group (preferably having 6 to 22 carbon atoms, more preferably having 6 to 18 carbon atoms, and still more preferably having 6 to 10 carbon atoms) or an aliphatic hydrocarbon group (preferably having 1 to 24 carbon atoms, more preferably having 1 to 12 carbon atoms, and still more preferably having 1 to 6 carbon atoms) is preferable, and among them, a cyclic or chain (linear or branched) alkyl group (preferably having 1 to 12 carbon atoms, more preferably having 1 to 6 carbon atoms, and still more preferably having 1 to 3 carbon atoms) or a group including a polymerizable group is preferable.

Specific examples of a structure of the silicon-containing compound include the following examples of Formulae (s-1) to (s-9) in terms of partial structure. Q in the formulae is a group including the above-described polymerizable group Qp. A plurality of these structures may be present in the compound, or may be present in combination.

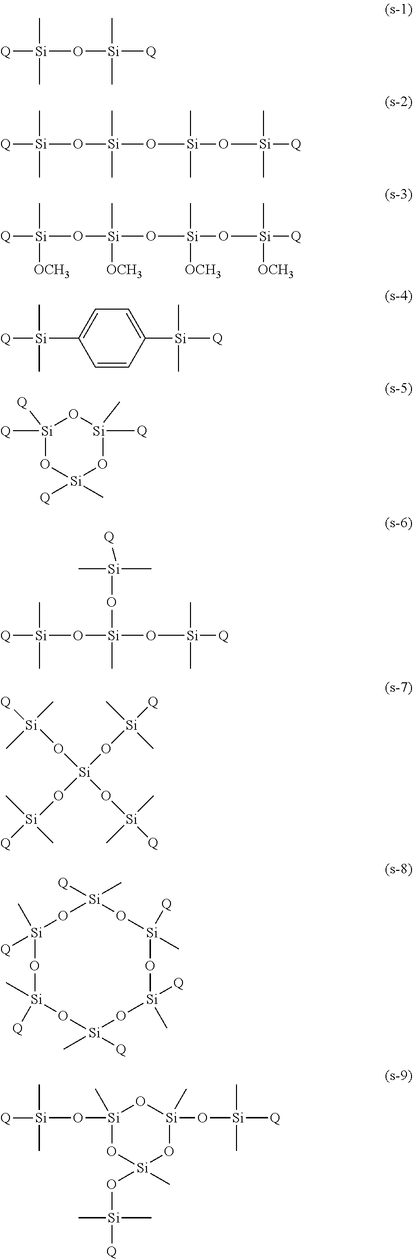

The silicon-containing compound is preferably a reactant of a silicone resin and a compound having a polymerizable group.

As the above-described silicone resin, a reactive silicone resin is preferable.

Examples of the reactive silicone resin include a modified silicone resin having the above-described silicone skeleton, and for example, a monoamine-modified silicone resin, a diamine-modified silicone resin, a special amino-modified silicone resin, an epoxy-modified silicone resin, an alicyclic epoxy-modified silicone resin, a carbinol-modified silicone resin, a mercapto-modified silicone resin, a carboxy-modified silicone resin, a hydrogen-modified silicone resin, an amino-polyether-modified silicone resin, an epos y-polyether-modified silicone resin, an epoxy-aralkyl-modified silicone resin, and the like can be mentioned.

As the above-described having a polymerizable group, a compound having a polymerizable group and a group capable of reacting with an alkoxysityl group or a silanol group is preferable, and a compound having a polymerizable group and a hydroxy group is more preferable.

Moreover, in a case where the above-described modified silicone resin is used as the silicone resin, as the above-described compound having a polymerizable group, a compound having a polymerizable group and a group which reacts with an amino group, an epoxy group, a mercapto group, a carboxy group, and the like, which are included in the above-described modified silicone resin, may be used.

A preferred aspect of the polymerizable group in the above-described compound having a polymerizable group is the same as the preferred aspect of the polymerizable group in the above-described polymerizable compound.

As the above-described compound having a polymerizable group, among them, hydroxyalkyl (meth)acrylate is preferable, and 2-hydroxyethyl (meth)acrylate is more preferable.

More specifically, a reactant of a compound having a polymerizable group and a group (for example, a hydroxy group) capable of reacting with an alkoxysilyl group or a silanol group and a silicone resin having an alkoxysilyl group or a silanol group is preferable.

### Ring-Containing Compound

Examples of a cyclic structure of the compound (ring-containing compound) containing a ring include an aromatic ring and an alicyclic ring. Examples of the aromatic ring include an aromatic hydrocarbon ring and an aromatic heterocyclic ring.

The aromatic hydrocarbon ring preferably has 6 to 22 carbon atoms, more preferably has 6 to 18 carbon atoms, and still more preferably has 6 to 10 carbon atoms. Specific examples of the aromatic hydrocarbon ring include a benzene ring, a naphthalene ring, an anthracene ring, a phenanthrene ring, a phenalene ring, a fluorene ring, a benzocyclooctene ring, an acenaphthylene ring, a biphenylene ring, an indene ring, an indane ring, a triphenylene ring, a pyrene ring, a chrysene ring, a perylene ring, and a tetrahydronaphthalene ring. Among them, a benzene ring or a naphthalene ring is preferable, and a benzene ring is more preferable. The aromatic ring may have a structure in which a plurality of rings is linked to each other, and examples thereof include a biphenyl structure and a diphenylalkane structure (for example, 2,2-diphenylpropane) (the aromatic hydrocarbon ring specified here is referred to as aCy).

The aromatic heterocyclic ring preferably has 1 to 12 carbon atoms, more preferably has 1 to 6 carbon atoms, and still more preferably has 1 to 5 carbon atoms. Specific examples thereof include a thiophene ring, a furan ring, a dibenzofuran ring, a pyrrole ring, an imidazole ring, a benzimidazole ring, a pyrazole ring, a triazole ring, a tetrazole ring, a thiazole ring, a thiadiazole ring, an oxadiazole ring, an oxazole ring, a pyridine ring, a pyrazine ring, a pyrimidine ring, a pyridazine ring, an isoindole ring, an indole ring, an indazole ring, a purine ring, a quinolidine ring, an isoquinoline ring, a quinoline ring, a phthalazinc ring, a naphthylidine ring, a quinoxaline ring, a quinazoline ring, a cinnoline ring, a carbazole ring, an aclysine ring, a phenazine ring, a phenothiazine ring, a phenoxathiin ring, and a phenoxazine ring (the aromatic heterocyclic ring specified here is referred to as hCy).

The alicyclic ring preferably has 3 to 22 carbon atoms, more preferably has 4 to 18 carbon atoms, and still more preferably has 6 to 10 carbon atoms. Specific examples of the aliphatic hydrocarbon ring include a cyclopropane ring, a cyclobutane ring, a cyclobutene ring, a cyclopentane ring, a cyclohexane ring, a cyclohexene ring, a cycloheptane ring, a cyclooctane ring, a dicyclopentadiene ring, a spirodecane ring, a spirononane ring, a tetrahydrodicyclopentadiene ring, an octahydronaphthalene ring, a decahydronaphthalene ring, a hexahydroindane ring, a bornane ring, a norbornane ring, a norbomene ring, a isobomane ring, a tricyclodecane ring, a tetracyclododecane ring, and an adamantane ring. Examples of the aliphatic hetero ring include a pyrrolidine ring, an imidazolidine ring, a piperidine ring, a piperazine ring, a morpholine ring, an oxirane ring, an oxetane ring, an oxorane ring, an oxane ring, and a dioxane ring (the alicyclic ring specified here is referred to as fCy).

In the present invention, in a case where the specific polymerizable compound is a ring-containing compound, a compound containing an aromatic hydrocarbon ring is preferable, and a compound having a benzene ring is more preferable. Examples thereof include a compound having a structure represented by Formula (C-1).

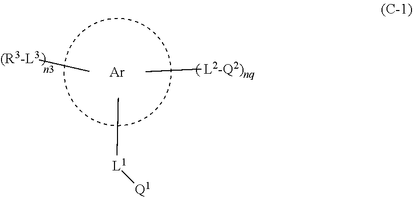

In the formula, Ar represents the above-described aromatic hydrocarbon ring or aromatic heterocyclic ring.

L¹ and L² are each independently a single bond or a linking group. Examples of the linking group include an oxygen atom (oxy group), a carbonyl group, an amino group, an alkylene group (preferably having 1 to 12 carbon atoms, more preferably having 1 to 6 carbon atoms, and still more preferably 1 to 3 carbon atoms), and a group of a combination of these groups. Among them, a (poly)alkyleneoxy group is preferable. The (poly)alkyleneoxy group may be a group having one alkyleneoxy group or a group in which a plurality of alkyleneoxy groups is repeatedly linked. Moreover, an order of the alkylene group and the oxy group is not limited. The repetition number of the alkyleneoxy group is preferably 1 to 24, more preferably 1 to 12, and still more preferably 1 to 6. Moreover, the (poly)alkyleneoxy group may be intervened with an alkylene group (preferably having 1 to 24 carbon atoms, more preferably having 1 to 12 carbon atoms, and still more preferably having 1 to 6 carbon atoms) in relation to the ring Ar which is a mother nucleus or the polymerizable group Q. Therefore, (poly)alkyleneoxy=alkylene group may be used.

R³ is an optional substituent, and examples thereof include an alkyl group (preferably having 1 to 12 carbon atoms, more preferably having 1 to 6 carbon atoms, and still more preferably having 1 to 3 carbon atoms), an alkenyl group (preferably having 2 to 12 carbon atoms, more preferably having 2 to 6 carbon atoms, and still more preferably having 2 or 3 carbon atoms), an aryl group (preferably having 6 to 22 carbon atoms, more preferably having 6 to 18 carbon atoms, and still more preferably having 6 to 10 carbon atoms), an arylalkyl group (preferably having 7 to 23 carbon atoms, more preferably having 7 to 19 carbon atoms, and still more preferably having 7 to 11 carbon atoms), a hydroxy group, a carboxy group, an alkoxy group (preferably having 1 to 24 carbon atoms, more preferably having 1 to 12 carbon atoms, and still more preferably having 1 to 6 carbon atoms), an acyl group (preferably having 2 to 12 carbon atoms, more preferably having 2 to 6 carbon atoms, and still more preferably having 2 or 3 carbon atoms; also preferably an alkylcarbonyl group), and an aryloyl group (preferably having 7 to 23 carbon atoms, more preferably having 7 to 19 carbon atoms, and still more preferably having 7 to II carbon atoms).

L³ is a single bond or a linking group. Examples of the linking group include the examples of L¹ and L² described above.

n3 is preferably 3 or less, more preferably 2 or less, still more preferably 1 or less, and particularly preferably 0.

Q¹ and Q² are each independently a polymerizable group, and the example of the above-described polymerizable group Qp is preferable.

In the ring-containing compound, in a case where the number of side chains having a polymerizable group is increased, it is possible to form a strong crosslinking structure during curing, and the resolution tends to be improved. From this viewpoint, nq is preferably 2 or more. The upper limit thereof is preferably 6 or less, more preferably 4 or less, and still more preferably 3 or less.

Similarly, from the viewpoint of easily forming a uniform crosslinking structure, in a case where a group including a polymerizable group or a substituent is introduced into the cyclic structure, it is preferable that the substituents are arranged in series.

### Dendrimer-Type Compound

The specific polymerizable compound may be a dendrimer-type compound. The dendrimer means a dendritic polymer having a structure which branches regularly from a center. The dendrimer is composed of a central molecule (stem) called as a core and a side chain portion (branch) called as a dendron. As a whole, a fan-shaped compound is common, but a dendrimer in which dendrons are spread in a semicircular or circular shape may be used. A group having a polymerizable group can be introduced into a dendron portion (for example, a terminal portion away from the core) of the dendrimer to obtain the polymerizable compound. In a case where a (meth)acryloyl group is used as the polymerizabie group to be introduced, a dendrimer-type polyfunctional (meth)acrylate can be obtained.

For the dendrimer-type compound, for example, matters described in JP5512970B can be referred to, the description of which is incorporated in the present specification.

### Polymerizable Group Equivalent

A polymerizable group equivalent of the specific polymerizable compound is preferably 130 or more, more preferably 150 or more, still more preferably 160 or more, even more preferably 190 or more, and even still more preferably 240 or more. The upper limit value of the polymerizable group equivalent is preferably 2,500 or less, more preferably 1,800 or less, still more preferably 1,000 or less, even more preferably 500 or less, and even still more preferably 350 or less, and may be 300 or less.

The polymerizable group equivalent is calculated by the following expression.

(Polymerizable group equivalent)=(Number-average molecular weight of polymerizable compound)/(Number of polymerizabie groups in polymerizable compound)

In a case where the polymerizable group equivalent of the specific polymerizable compound is the above-described lower limit value or more, it is considered that the elastic modulus during curing is in an appropriate range and the releasability is excellent. On the other hand, in a case where the polymerizable group equivalent is the above-described upper limit value or less, it is considered that a crosslink density of the cured substance pattern is in an appropriate range and the resolution of the transfer pattern is excellent.

In a case of the silicon-containing compound, the number of polymerizable groups in the specific polymerizable compound is preferably 2 or more, more preferably 3 or more, and still more preferably 4 or more in one molecule. The upper limit thereof is preferably 50 or less, more preferably 40 or less, still more preferably 30 or less, and even more preferably 20 or less.

In a case of the ring-containing compound, it is preferable to be 2 or more in one molecule. The upper limit thereof is preferably 4 or less and more preferably 3 or less.

Alternatively, in a case of the dendrimer-type compound, it is preferable to be 5 or more, more preferably 10 or more, and still more preferably 20 or more in one molecule. The upper limit thereof is preferably 1000 or less, more preferably 500 or less, and still more preferably 200 or less.

### Viscosity

A viscosity of the specific polymerizable compound at 23° C. is preferably 100 mPa·s or greater, more preferably 120 mPa·s or greater, and still more preferably 150 mPa·s or greater. The upper limit value of the above-described viscosity is preferably 2,000 mPa·s or lower, more preferably 1,500 mPa·s or lower, and still more preferably 1,200 mPa·s or lower.

Unless otherwise specified, the viscosity in the present specification is a value measured with an E-type rotational viscometer RE85L manufactured by TOKI SANGYO CO., LTD. and a standard cone rotor (1° 34′×R24) in a state where a temperature of a sample cup is adjusted to 23° C. Other details regarding the measurement are in accordance with JIS Z 8803:2011. Two samples are produced for one level and are respectively measured three times. An arithmetic mean value of a total of six times is adopted as an evaluation value.

### Other Polymerizable Compounds

The composition for forming an imprint pattern according to the embodiment of the present invention may include a polymerizable compound other than the specific polymerizable compound as the polymerizable compound.

The other polymerizable compounds may be a monofunctional polymerizable compound having one polymerizable group, or a polyfunctional polymerizable compound having two or more polymerizable groups. The composition for forming an imprint pattern according to the embodiment of the present invention preferably includes a polyfunctional polymerizable compound, and more preferably includes both a polyfunctional polymerizable compound and a monofunctional polymerizable compound.

The polyfunctional polymerizable compound preferably includes at least one kind of a bifunctional polymerizable compound or a trifunctional polymerizable compound, and more preferably includes at least one kind of bifunctional polymerizable compounds.

### Molecular Weight

A molecular weight of the other polymerizable compound is preferably less than 2,000, more preferably 1,500 or less, and still more preferably 1,000 or less, and may be 800 or less. The lower limit value thereof is preferably 100 or more.

### Polyfunctional Polymerizable Compound

The number of polymerizable groups in the polyfunctional polymerizable compound as the other polymerizable compounds is 2 or more, preferably 2 to 7, more preferably 2 to 4, still more preferably 2 or 3, and even more preferably 2.

In the present invention, it is preferable to include a compound represented by Formula (2). By using such a compound, an adhesiveness, a releasing force, and a temporal stability tend to be well-balanced and more excellent.

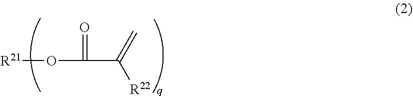

In the formula, R²¹ is a q-valent organic group, R²² is a hydrogen atom or a methyl group, and q is an integer of 2 or more. q is preferably an integer of 2 to 7, more preferably an integer of 2 to 4, still more preferably 2 or 3, and even more preferably 2.

R²¹ is preferably a divalent to heptavalent organic group, more preferably a divalent to tetravalent organic group, still more preferably a divalent or trivalent organic group, and even more preferably a divalent organic group. R²¹ is preferably a hydrocarbon group having at least one of a linear structure, a branched structure, or a cyclic structure. The number of carbon atoms in the hydrocarbon group is preferably 2 to 20 and more preferably 2 to 10.

In a case where R²¹ is a divalent organic group, an organic group represented by Formula (1-2) is preferable.

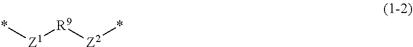

In the formula, it is preferable that Z¹ and Z¹ are each independently a single bond, —O—, -Alk-, or -Alk-O—. Alk represents an alkylene group (the number of carbon atoms is preferably 1 to 12, more preferably 1 to 6, and still more preferably 1 to 3), and may have a substituent as long as the effects of the present invention can be obtained.

R⁹ is preferably a single bond, a linking group selected from Formulae (9-1) to (9-10), or a combination thereof. Among them, a linking group selected from Formulae (9-1) to (9-3), (9-7), and (9-8) is preferable.

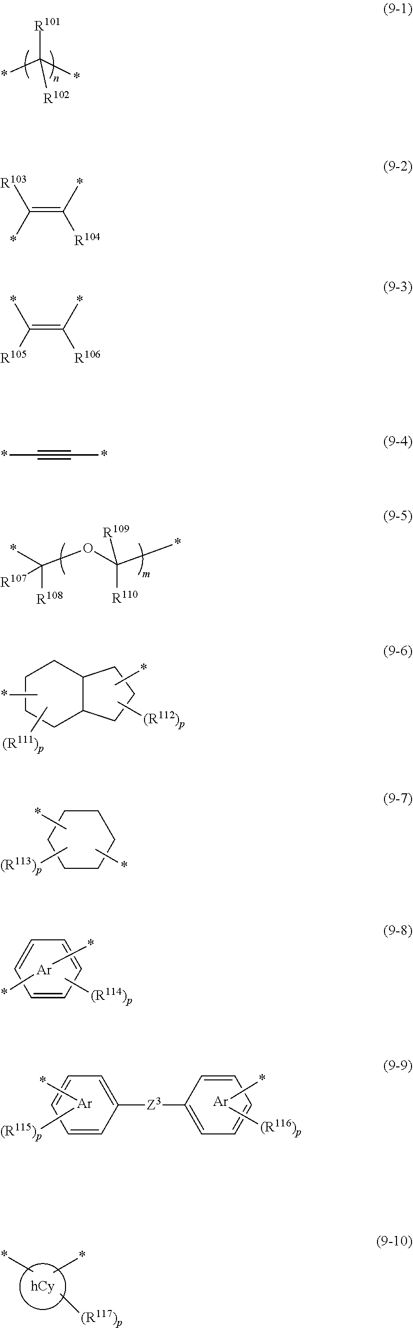

R¹⁰¹ to R¹¹⁷ are optional substituents. Among them, an alkyl group (the number of carbon atoms is preferably 1 to 12, more preferably 1 to 6, and still more preferably 1 to 3), an aralkyl group (the number of carbon atoms is preferably 7 to 21, more preferably 7 to 15, and still more preferably 7 to 11), an aryl group (the number of carbon atoms is preferably 6 to 22, more preferably 6 to 18, and still more preferably 6 to 10), a thienyl group, a furyl group, a (meth)acryloyl group, a (meth)acryloyloxy group, or a (meth)acryloyloxyalkyl group (the number of carbon atoms in the alkyl group is preferably 1 to 24, more preferably 1 to 12, and still more preferably 1 to 6) is preferable. R¹⁰¹ and R¹⁰², R¹⁰³ and R¹⁰⁴, R¹⁰⁵ and R¹⁰⁶, R¹⁰⁷ and R¹⁰⁸, R¹⁰⁹ and R¹¹⁰, a plurality of R¹¹¹'s, a plurality of R¹¹²'s, a plurality of R¹¹³'s, a plurality of R¹¹⁴'s, a plurality of R¹¹⁵'s, a plurality of R¹¹⁶'s, and a plurality of R¹¹⁷'s may be respectively bonded to each other to form a ring.

Ar is an arylene group (the number of carbon atoms is preferably 6 to 22, more preferably 6 to 1$, and still more preferably 6 to 10), and specific examples thereof include a phenylene group, a naphthalenediyl group, an anthracenediyl group, a phenanthrenediyl group, and a fluorenediyl group.

hCy¹ is a heterocyclic group (the number of carbon atoms is preferably 1 to 12, more preferably 1 to 6, and still more preferably 2 to 5), and is more preferably a 5-membered ring or a 6-membered ring. Specific examples of a hetero ring constituting hCy¹ include the above-described aromatic heterocyclic ring hCy, a pyrrolidone ring, a tetrahydrofuran ring, a tetrahydropyran ring, and a morpholine ring, and among them, a thiophene ring, a furan ring, or a dibenzofuran ring is preferable.

n and m are each a natural number of 100 or less, and are each preferably 1 to 12, more preferably 1 to 6, and still more preferably 1 to 3.

p is 0 or more and is an integer equal to or less than the maximum number of groups which can be substituted for each ring. In the respective cases, the upper limit values are independently preferably equal to or less than half of the maximum number of the substitutable group, more preferably 4 or less, and still more preferably 2 or less.

The polyfunctional polymerizable compound is preferably represented by Formula (2-1).

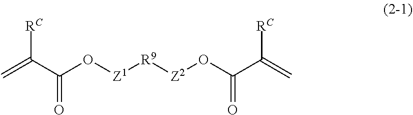

R⁹, Z¹, and Z² in Formula (2-1) have the same definitions as R⁹, Z¹, and Z² in Formula (1-2), respectively, and preferred ranges thereof are also the same.

These polyfunctional polymerizable compounds may be included only one kind or two or more kinds.

A kind of an atom constituting the polyfunctional polymerizable compound used in the present invention is not particularly specified, but the other polyfunctional polymerizable compound is preferably constituted of only atoms selected from a carbon atom, an oxygen atom, a hydrogen atom, and a halogen atom, and more preferably constituted of only atoms selected from a carbon atom, an oxygen atom, and a hydrogen atom.

Moreover, a polymerizable group equivalent of the polyfunctional polymerizable compound, which is defined as above, is preferably 150 or more, more preferably 160 or more, still more preferably 190 or more, and even more preferably 240 or more. The upper limit thereof is preferably 2,500 or less, more preferably 1,800 or less, and still more preferably 1,000 or less.

The polyfunctional polymerizable compound preferably has a cyclic structure. Examples of a cyclic structure thereof include the examples of the aromatic hydrocarbon ring aCy, the aromatic heterocyclic ring hCy, and the alicyclic ring fCy.

Examples of the other polymerizable compounds include the compounds described in paragraphs 0017 to 0024 and Examples of JP2014-090133A, the compounds described in paragraphs 0024 to 0089 of JP2015-009171A, the compounds described in paragraphs 0023 to 0037 of JP2015-070145A, and the compounds described in paragraphs 0012 to 0039 of WO2016/152597A, the contents of which are cited and incorporated in the present specification.

### Monofunctional Polymerizable Compound

The type of the monofunctional polymerizable compound used in the present invention is not particularly defined as long as it does not depart from the spirit of the present invention. It is preferable that the monofunctional polymerizable compound used in the present invention has a cyclic structure, or has a linear or branched hydrocarbon chain having 4 or more carbon atoms. In the present invention, only one kind or two or more kinds of the monofunctional polymerizable compounds may be included.

The monofunctional polymerizable compound used in the present invention is preferably a liquid at 25° C.

In the present invention, the compound which is a liquid at 25° C. means a compound having fluidity at 25° C., for example, a compound having a viscosity at 25° C. of 1 to 100,000 mPa·s. The viscosity of the monofunctional polymerizable compound at 25° C. is, for example, more preferably 10 to 20,000 mPa·s and still more preferably 100 to 15,000 mPa·s.

By using a compound which is a liquid at 25° C., a configuration in which a solvent is substantially not included can be adopted. Moreover, a distillation which will be described later is easy. Here, the expression “not substantially include a solvent” means, for example, that the content of the solvent in the composition for forming an imprint pattern according to the embodiment of the present invention is 5% by mass or lower, further 3% by mass or lower, and particularly 1% by mass or lower.

A viscosity of the monofunctional polymerizable compound used in the present invention at 25° C. is preferably 100 mPa·s or lower, more preferably 10 mPa·s or lower, still more preferably 8 mPa·s or lower, and even more preferably 6 mPa·s or lower. By setting the viscosity of the monofunctional polymerizable compound at 25° C. to be equal to or lower than the upper limit value, the viscosity of the composition for forming an imprint pattern can be reduced, and thus filling properties tend to be improved. The lower limit value thereof is not particularly specified, but can be, for example, 1 mPa·s or greater.

The monofunctional polymerizable compound used in the present invention is preferably a monofunctional (meth)acrylic monomer and more preferably monofunctional acrylate.

A kind of an atom constituting the monofunctional polymerizable compound used in the present invention is not particularly specified, but the other polyfunctional polymerizable compound is preferably constituted of only atoms selected from a carbon atom, an oxygen atom, a hydrogen atom, and a halogen atom, and more preferably constituted of only atoms selected from a carbon atom, an oxygen atom, and a hydrogen atom.

The monofunctional polymerizable compound used in the present invention preferably has a plastic structure. For example, it is preferable that at least one kind of the monofunctional polymerizable compounds used in the present invention includes one group selected from the group consisting of the following (1) to (3).

(1) Group (hereinafter, referred to as a “group (1)” in some cases) which has at least one of an alkyl chain or an alkenyl chain and at least one of an alicyclic ring structure or an aromatic ring structure, and has the total number of carbon atoms of 7 or more

(2) Group (hereinafter, referred to as a “group (2)” in some cases) including an alkyl chain having 4 or more carbon atoms

(3) Group (hereinafter, referred to as a “group (3)” in some cases) including an alkenyl chain having 4 or more carbon atoms

With such a configuration, an elastic modulus of a cured film can be efficiently reduced while reducing the addition amount of the monofunctional polymerizable compound included in the composition for forming an imprint pattern. Moreover, interfacial energy with the mold is reduced, and thus an effect of reducing a releasing force (effect of improving releasability) can be enhanced.

In the groups (1) to (3), the alkyl chain and the alkenyl chain may be linear, branched, or cyclic, and are each independently preferably linear or branched. Moreover, it is preferable that the groups (1) to (3) have at least one of the above-described alkyl chain or alkenyl chain at a terminal of the monofunctional polymerizable compound, that is, have at least one of the alkyl group or the alkenyl group. With such a structure, the releasability can be further improved.

The alkyl chain and the alkenyl chain may each independently include an ether group (—O—) in the chain, but it is preferable that an ether group is not included from the viewpoint of improvement in the releasability.

### Group (1)

The total number of carbon atoms in the group (1) is preferably 35 or less and more preferably 10 or less.

As the cyclic structure, a single ring or a fused ring of 3- to 8-membered rings is preferable. The number of rings constituting the fused ring is preferably 2 or 3. The cyclic structure is more preferably a 5-membered ring or a 6-membered ring and still more preferably a 6-membered ring. Moreover, a single ring is more preferable. As the cyclic structure in the group (1), a cyclohexane ring, a benzene ring, and a naphthalene ring are more preferable, and a benzene, ring is particularly preferable. Moreover, the cyclic structure is preferably an aromatic ring structure.

The number of cyclic structures in the group (1) may be 1 or may be 2 or more, but is preferably 1 or 2 and more preferably 1. Furthermore, in a case of the fused ring, the fused ring is considered as one cyclic structure,

### Group (2)

The group (2) is a group including an alkyl chain having 4 or more carbon atoms, and preferably a group (that is, an alkyl group) consisting of an alkyl chain having 4 or more carbon atoms. The number of carbon atoms in the alkyl chain is preferably 7 or more and more preferably 9 or more. The upper limit value of the number of carbon atoms in the alkyl chain is not particularly limited, but can be, for example, 25 or less. Moreover, a compound in which some carbon atoms of the alkyl chain are substituted with silicon atoms can also be exemplified as the monofunctional polymerizable compound.

### Group (3)

The group (3) is a group including an alkenyl chain having 4 or more carbon atoms, and preferably a group (that is, an alkylene group) consisting of an alkenyl chain having 4 or more carbon atoms. The number of carbon atoms in the alkenyl chain is preferably 7 or more and more preferably 9 or more. The upper limit value of the number of carbon atoms in the alkenyl chain is not particularly limited, but can be, for example, 25 or less.

The monofunctional polymerizable compound used in the present invention is preferably a compound in which any one or more of the group (1), (2), or (3) are bonded to a polymerizable group directly or through a linking group, and more preferably a compound in which any one of the group (1), (2), or (3) is directly bonded to a polymerizable group. Examples of the linking group include —O—, —C(═O)—, —NH—, and a combination thereof.

Specific examples of the monofunctional polymerizable compound include the compounds described in paragraph 0013 of WO2018/025739A, but the monofunctional polymerizable compound is not limited thereto.

In a case where the composition for forming an imprint pattern according to the embodiment of the present invention includes a monofunctional polymerizable compound, a content of the monofunctional polymerizable compound with respect to the mass of the total polymerizable compound included in the composition for forming an imprint pattern is, as a lower limit value, preferably 1% by mass or greater, more preferably 3% by mass or greater, still more preferably 5% by mass or greater, and even more preferably 7% by mass or greater. Moreover, the upper limit value thereof is more preferably 29% by mass or lower, still more preferably 27% by mass or lower, even more preferably 25% by mass or lower, further still more preferably 20% by mass or lower, and further still more preferably 15% by mass or lower. By setting the amount of the monofunctional polymerizable compound with respect to the total polymerizable compound to the above-described lower limit value or greater, the releasability can be improved, and thus it is possible to suppress defects and mold breakage during mold release. Furthermore, by setting the amount to be equal to or less than the upper limit value, the Tg of the cured film formed of the composition for forming an imprint pattern can be increased, and thus resistance to etching processing, in particular, waviness of a pattern during etching can be suppressed.

In the present invention, monofunctional polymerizable compounds other than the above-described monofunctional polymerizable compounds may be used as long as the compounds do not depart from the spirit of the present invention, and examples thereof include the monofunctional polymerizable compounds among the polymerizable compounds described in JP2014-170949A, the contents of which are incorporated in the present specification.

### Content

A content of the polymerizable compound in the composition for forming an imprint pattern is preferably 50% by mass or greater, more preferably 70% by mass or greater, still more preferably 90% by mass or greater, and particularly preferably 95% by mass or greater with respect to the total solid content of the composition. The upper limit thereof is preferably 99.9% by mass or lower. By containing the polymerizable compound in an amount of the above-described lower limit value or greater, sufficient light-transmitting property is obtained, and in a case where a film is cured by light irradiation, curing properties in a deep portion of the film is improved, which is preferable. The polymerizable compound may be used alone or in combination of a plurality of kinds. In a case where a plurality of kinds is used in combination, the total amount thereof is preferably within the above-described range.

### Polymerization Initiator

The composition for forming an imprint pattern according to the embodiment of the present invention includes a polymerization initiator.

The polymerization initiator may be a photopolymerization initiator or a thermal polymerization initiator, but from the viewpoint of realizing the curing of the pattern by exposure, a photopolymerization initiator is preferable.

Moreover, the polymerization initiator may be a radical polymerization initiator or a cationic polymerization initiator, and the type of the polymerization initiator may be appropriately selected according to the type of the polymerizable compound. Among them, a radical polymerization initiator is preferable, and a photoradical polymerization initiator is more preferable.

### Photopolymerization Initiator

In the present invention, the maximum value of a molar absorption coefficient of the photopolymerization initiator in an acetonitrile solution in a wavelength range of 250 to 400 nm is referred to as an “absorption coefficient B”.

The maximum value of the absorption coefficient B of the polymerization initiator is preferably 5,000 L(mol·cm) or greater, more preferably 10,000 L(mol·cm) or greater, and still more preferably 25,000 L(mol·cm) or greater. The upper limit of the maximum value of the absorption coefficient B can be, for example, 100,000 L(mol·cm) or lower, and further 50,000 L(mol·cm) or lower.

Examples of the photopolymerization initiator include an oxime ester-based photopolymerization initiator, an acylphosphine oxide-based photopolymerization initiator, an allyloylphosphine oxide-based photopolymerization initiator, and an alkylphenone-based photopolymerization initiator. Among them, in the composition for forming an imprint pattern according to the embodiment of the present invention, it is preferable to use an oxime ester-based photopolymerization initiator. Here, the oxime ester-based photopolymerization initiator refers to a compound having a linking structure represented by Formula (1) in a molecule, and preferably has a linking structure represented by Formula (2). * in the formulae indicates a bonding site bonded to an organic group.

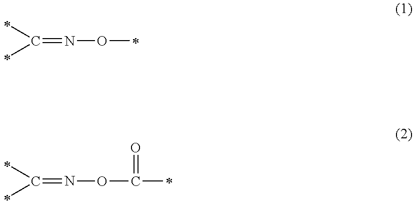

A molecular weight of the photopolymerization initiator is not particularly limited, but is preferably 100 or more, more preferably 150 or more, and still more preferably 200 or more. The upper limit thereof is preferably 2,000 or less, more preferably 1,500 or less, and still more preferably 1,000 or less.

Specific examples of the photopolymerization initiator include IRGACURE 819, OXE-01, OXE-02, OXE-04, Darocure 1173, and Irgacure TPO manufactured by BASF SE, and NCI-831 and NCI-831E manufactured by ADEKA Corporation,

### Thermal Polymerization Initiator

The composition for forming an imprint pattern according to the embodiment of the present invention may include a thermal polymerization initiator. The thermal polymerization initiator may be selected depending on the type of the polymerizable compound, but a thermal radical polymerization initiator is preferable.

In a case where the composition for forming an imprint pattern according to the embodiment of the present invention includes a thermal polymerization initiator, for example, by heating the composition for forming an imprint pattern while pressing the composition for forming an imprint pattern between the mold and the support, a cured substance in a patterned shape can be obtained.

Moreover, the composition for forming an imprint pattern according to the embodiment of the present invention may include the photopolymerization initiator and the thermal polymerization initiator.

Specific examples of the thermal polymerization initiator include the compounds described in paragraphs 0074 to 0118 of JP2008-063554A.

### Content

A content of the polymerization initiator is preferably 0.5% by mass or greater, more preferably 1.0% by mass or greater, and still more preferably 2.0% by mass or greater with respect to the total solid content of the composition for forming an imprint pattern. The upper limit value thereof is preferably 8.0% by mass or lower and more preferably 6.0% by mass or lower. In a case where the content of the polymerization initiator is the above-described lower limit value or greater, sufficient curing properties can be ensured and good resolution can be exhibited. On the other hand, in a case of being the above-described upper limit value or less, it is possible to prevent the initiator from precipitating and inducing coating defects during coating or refrigerated storage.

The polymerization initiator may be used alone or in combination of a plurality thereof. In a case where a plurality thereof is used, the total amount thereof is within the above-described range.

### Release Agent

The composition for forming an imprint pattern according to the embodiment of the present invention preferably contains a release agent. A content of the release agent is 0.1% by mass or greater with respect to the total solid content of the composition, preferably 0.3% by mass or greater, more preferably 0.5% by mass or greater, and still more preferably 0.6% by mass or greater. The upper limit value thereof is lower than 1.0% by mass, preferably 0.9% by mass or lower and more preferably 0.85% by mass or lower. In a case where the content of the release agent is the above-described lower limit value or greater, the releasability is improved, and peeling of the cured film and damage to the mold during mold release can be prevented. Moreover, in a case of being the above-described upper limit value or lower, a pattern strength during curing is not excessively lowered due to the influence of the release agent and a synergistic effect with the polymerizable compound and the polymerization initiator is exhibited, and thus good resolution can be realized.

The release agent may be used alone or in combination of a plurality thereof. In a case where a plurality thereof is used, the total amount thereof is within the above-described range.

The type of the release agent is not particularly limited, but it is preferable to have a function of segregating at an interface with the mold and effectively promoting mold release from the mold. In the present invention, it is preferable that the release agent does not substantially include a fluorine atom and a silicon atom. The expression “not substantially include” means that the total amount of the fluorine atom and the silicon atom is 1% by mass or lower of the release agent, preferably 0.5% by mass or lower, more preferably 0.1% by mass or lower, and still more preferably 0.01% by mass or lower. From the viewpoint of achieving high releasability of the film and excellent processing resistance to etching and the like, it is preferable that the release agent which does not substantially include a fluorine atom and a silicon atom is used in the composition for forming an imprint pattern.

Specifically, the release agent used in the present invention is preferably a surfactant. Alternatively, it is preferably an alcohol compound having at least one hydroxy group at a terminal, or a compound ((poly)alkylene glycol compound) having a (poly)alkylene glycol structure in which a hydroxy group is etherified. The surfactant and the (poly)alkylene glycol compound are preferably a non-polymerizable compound not having the polymerizable group Qp. The (poly)alkylene glycol means that an alkylene glycol structure may be one or a plurality of the alkylene glycol structures may be repeatedly linked.

### Surfactant

As the surfactant which can be used as the release agent in the present invention, a nonionic surfactant is preferable.

The nonionic surfactant is a compound having at least one hydrophobic moiety and at least one nonionic hydrophilic moiety. The hydrophobic moiety and the nonionic hydrophilic moiety may each be at a terminal of a molecule, or inside. The hydrophobic moiety is constituted of a hydrophobic group selected from a hydrocarbon group, a fluorine-containing group, and a Si-containing group, and the number of carbon atoms in the hydrophobic moiety is preferably 1 to 25, more preferably 2 to 15, still more preferably 4 to 10, and even more preferably 5 to 8. The nonionic hydrophilic moiety preferably has at least one group selected from the group consisting of an alcoholic hydroxy group, a phenolic hydroxy group, an ether group (preferably, a (poly)alkyleneoxy group and a cyclic ether group), an amide group, an imide group, a ureide group, a urethane group, a cyano group, a sulfonamide group, a lactone group, a lactam group, and a cyclocarbonate group. Among them, a compound having an alcoholic hydroxy group or an ether group (preferably, a (poly)alkyleneoxy group and a cyclic ether group) is more preferable.

### Alcohol Compound and (Poly)alkylene Glycol Compound

As described above, examples of a preferred release agent used in the composition for forming an imprint pattern according to the embodiment of the present invention include an alcohol compound having at least one hydroxy group at a terminal and a (poly)alkylene glycol compound in which a hydroxy group is etherified.

Specifically, the (poly)alkylene glycol compound preferably has an alkyleneoxy group or a polyalkyleneoxy group, and more preferably has a (poly)alkyleneoxy group including an alkylene group having 1 to 6 carbon atoms. Specifically, it is preferable to have a (poly)ethyleneoxy group, a (poly)propyleneoxy group, a (poly)butyleneoxy group, or a mixed structure thereof, it is more preferable to have a (poly)ethyleneoxy group, a (poly)propyleneoxy group, or a mixed structure thereof, and it is still more preferable to have a (poly)propyleneoxy group. The (poly)alkylene glycol compound may be substantially constituted of only a (poly)alkyleneoxy structure, except for a substituent at a terminal. Here, the expression “substantially” means that constituent elements other than the (poly)alkyleneoxy structure account for 5% by mass or lower and preferably 1% by mass or lower of the entire compound. In particular, it is particularly preferable that the (poly)alkylene glycol compound includes a compound substantially constituted of only the (poly)propyleneoxy group.

The repetition number of alkyleneoxy groups in the (poly)alkylene glycol compound is preferably 3 to 100, more preferably 4 to 50, still more preferably 5 to 30, and even more preferably 6 to 20.

As long as the hydroxy group at the terminal is etherified, the (poly)alkylene glycol compound may have a hydroxy group at the remaining terminal, or may have a terminal hydroxy group in which a hydrogen atom is substituted. As a group in which the hydrogen atom of the terminal hydroxy group may be substituted, an alkyl group (that is, (poly)alkylene glycol alkyl ether) or an acyl group (that is, (poly)alkylene glycol ester) is preferable. A compound having a plurality (preferably, two or three) of (poly)alkylene glycol chains through a linking group can also be preferably used.

Preferred specific examples of the (poly)alkylene glycol compound include polyethylene glycol, polypropylene glycol (for example, manufactured by FUJIFILM Wako Pure Chemical Corporation), mono or dimethyl ether thereof, mono or dibutyl ether, mono or dioctyl ether, mono or dicetyl ether, monostearic acid ester, monooleic acid ester, polyoxyethylene glyceryl ether, polyoxypropylene glyceryl ether, polyoxyethylene lauryl ether, and trimethyl ether thereof.

The (poly)alkylene glycol compound is preferably a compound represented by Formula (P1) or (P2).

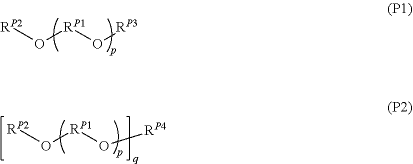

R^{P1} in the formulae is an alkylene group (preferably having 1 to 12 carbon atoms, more preferably having 1 to 6 carbon atoms, and still more preferably having 1 to 3 carbon atoms), which may be a chain group or a cyclic group and may be linear or branched. R^{P2} and R^{P3} are a hydrogen atom or an alkyl group (preferably having 1 to 36 carbon atoms, more preferably having 2 to 24 carbon atoms, and still more preferably having 3 to 12 carbon atoms), which may be a chain group or a cyclic group and may be linear or branched. p is preferably an integer of 1 to 24 and more preferably an integer of 2 to 12.

R^{P4} is a q-valent linking group, and is preferably a linking group composed of an organic group and more preferably a linking group composed of a hydrocarbon. Specific examples of the linking group composed of a hydrocarbon include a linking group of an alkane structure (preferably having 1 to 24 carbon atoms, more preferably having 2 to 12 carbon atoms, and still more preferably having 2 to 6 carbon atoms), a linking group of an alkene structure (preferably having 2 to 24 carbon atoms, more preferably having 2 to 12 carbon atoms, and still more preferably having 2 to 6 carbon atoms), and a linking group of an aryl structure (preferably having 6 to 22 carbon atoms, more preferably having 6 to 18 carbon atoms, and still more preferably having 6 to 10 carbon atoms).

q is preferably an integer of 2 to 8, more preferably an integer of o 6, and still more preferably an integer of 2 to 4.

A weight-average molecular weight of the alcohol compound or the (poly)alkylene glycol compound used as the release agent is preferably 150 to 6,000, more preferably 200 to 3,000, still more preferably 250 to 2,000, and even more preferably 300 to 1,200.

In addition, examples of a commercially available product of the (poly)alkylene glycol compound which can be used in the present invention include OLFINE E1010 (manufactured by Nissin Chemical Co., Ltd.) and Brij35 (manufactured by Kishida Chemical Co., Ltd.).

### Polymerization Inhibitor

The composition for forming an imprint pattern according to the embodiment of the present invention preferably includes at least one kind of polymerization inhibitors.

The polymerization inhibitor has a function of quenching (deactivating) reactive substances such as radicals generated from the photopolymerization initiator, plays a role of suppressing a reaction of the composition for forming an imprint pattern at a low exposure amount.

In particular, in a case of including the other polymerizable compounds, the polymerization inhibitor can be sufficiently dissolved, and the above-described effects are likely to be exhibited.

As the polymerization inhibitor, for example, hydroquinone, 4-methoxyphenol, di-tent-butyl-p-cresol, pyrogallol, p-tert-butylcatechol, 1,4-benzoquinone, diphenyl-p-benzoquinone, 4,4′-thiobis(3-methyl-6-tert-butylphenol), 2,2′-methylenebis(4-methyl-6-tert-butylphenol), N-nitroso-N-phenylhydroxyamine aluminum salt, phenothiazine, N-nitrosodiphenylamine, N-phenyl naphthylamine, ethylenediamine tetraacetic acid, 1,2-cyclohexanediamine tetraacetic acid, glycol ether diamine tetraacetic acid, 2,6-di-tert-butyl-4-methyl phenol, 5-nitroso-8-hydroxyquinoline, 1-nitroso-2-naphtoyl, 2-nitroso-1-naphtoyl, 2-nitroso-5-(N-ethyl-N-sulfopropylamino)phenol, N-nitroso-N-(1-naphthyl)hydroxyamine ammonium salt, bis(4-hydroxy-3,5-tert-butyl)phenylmethane, and the like are suitably used. In addition, the polymerization inhibitors described in paragraph 0060 of JP2015-127817A and the compounds described in paragraphs 0031 to 0046 of WO2015/125469A can also be used. Specific examples of a commercially available product of the polymerization inhibitor include Q-1300, Q-1301, and TBHQ (manufactured by FUJIFILM Wako Pure Chemical Corporation), and Quino Power series (manufactured by Kawasaki Kasei Chemicals Ltd.).

In addition, the following compounds can be used (Me is a methyl group).

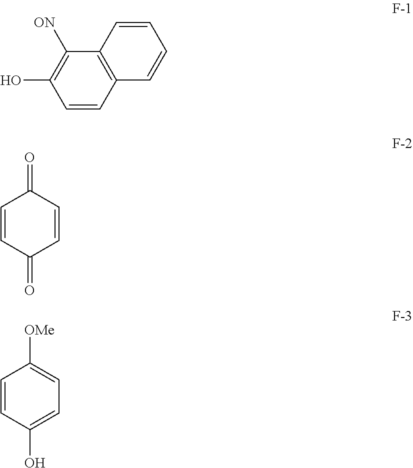

A content of the polymerization inhibitor is preferably 0.1% to 5% by mass and more preferably 0.5% to 3% by mass. In a case where this content is the above-described lower limit value or greater, a reactivity of the photopolymerization initiator can be effectively exhibited. Moreover, in a case of being the above-described upper limit value or lower, it is possible to prevent the transfer pattern from collapsing and to enable effective patterning.

The polymerization inhibitor may be used alone or in combination of a plurality thereof. In a case where a plurality thereof is used, it is preferable that the total amount thereof is within the above-described range.

### Solvent

The above-described composition for forming an imprint pattern may include a solvent. The solvent refers to a compound which is liquid at 23° C. and has a boiling point of 250° C. or lower. In a case of including a solvent, a content thereof is, for example, preferably 1% by mass or greater, more preferably 10% by mass or greater, and still more preferably 30% by mass or greater. Moreover, the above-described content is, for example, preferably 99.5% by mass or lower, more preferably 99% by mass or lower, and still more preferably 98% by mass or lower.

Among these, a first preferred aspect of the composition for forming an imprint pattern according to the embodiment of the present invention is an aspect in which the composition for forming an imprint pattern includes a solvent, and the content of the solvent is 90.0% to 99.0% by mass with respect to the total mass of the composition for forming an imprint pattern.

In the above-described first preferred aspect, the content of the solvent is preferably 95.0% by mass or greater and more preferably 97.0% by mass or greater.

Moreover, in the above-described first preferred aspect, the composition for forming an imprint pattern preferably includes the above-described specific polymerizable compound as the polymerizable compound.

A second preferred aspect of the composition for forming an imprint pattern according to the embodiment of the present invention is an aspect in which the composition for forming an imprint pattern does not include a solvent, or the composition for forming an imprint pattern includes a solvent and a content of the solvent is greater than 0% by mass and lower than 5% by mass with respect to the total mass of the composition for forming an imprint pattern.

In the above-described second preferred aspect, it is preferable that the solvent is not included or the content of the solvent is greater than 0% by mass and lower than 3% by mass, and it is more preferable that the solvent is not included or the content of the solvent is greater than 0% by mass and lower than 1% by mass.

Moreover, in the above-described second preferred aspect, the composition for forming an imprint pattern preferably includes the above-described other polymerizable compounds as the polymerizable compound.

In any of the above-described aspects, only one kind of the solvent may be included, or two or more kinds thereof may be included. In a case where two or more kinds thereof are included, the total amount thereof is preferably within the above-described range.

In the present invention, a boiling point of a component having the highest content of the solvent is preferably 200° C., or lower and more preferably 160° C., or lower. By setting the boiling point of the solvent to the above-described temperature or lower, it is possible to remove the solvent in the composition for forming an imprint pattern by performing baking. The lower limit value of the boiling point of the solvent is not particularly limited, but is preferably 60° C. or higher, more preferably 80° C. or higher, and still more preferably 100° C. or higher.

The solvent is preferably an organic solvent. The solvent is preferably a solvent having any one or more of an ester group, a carbonyl group, an alkoxy group, a hydroxy group, or an ether group.

As specific examples of the solvent, alkoxy alcohol, propylene glycol monoalkyl ether carboxylate, propylene glycol monoalkyl ether, lactic acid ester, acetic acid ester, alkoxypropionic acid ester, chain-like ketone, cyclic ketone, lactone, and alkylene carbonate are selected.

Examples of the alkoxy alcohol include methoxyethanol, ethoxyethanol, methoxypropanol (for example, 1-methoxy-2-propanol), ethoxypropanol (for example, 1-ethoxy-2-propanol), propoxypropanol (for example, 1-propoxy-2-propanol), methoxybutanol (for example, 1-methoxy-2-butanol and 1-methoxy-3-butanol), ethoxybutanol (for example, 1-ethoxy-2-butanol and 1-ethoxy-3-butanol), and methylpentanol (for example. 4-methyl-2-pentanol).

As the propylene glycol monoalkyl ether carboxylate, at least one selected from the group consisting of propylene glycol monomethyl ether acetate, propylene glycol monomethyl ether propionate, and propylene glycol monoethyl ether acetate is preferable, and propylene glycol monomethyl ether acetate is particularly preferable.

Moreover, as the propylene glycol monoalkyl ether, propylene glycol monomethyl ether or propylene glycol monoethyl ether is preferable.

As the lactic acid ester, ethyl lactate, butyl lactate, or propyl lactate is preferable.

As the acetic acid ester, methyl acetate, ethyl acetate, butyl acetate, isobutyl acetate, propyl acetate, isoamyl acetate, methyl formate, ethyl formate, butyl formate, propyl formate, or 3-methoxybutyl acetate is preferable.

As the alkoxypropionic acid ester, methyl 3-methoxypropionate (MMP) or ethyl 3-ethoxypropionate (EEP) is preferable.

As the chain-like ketone, 1-octanone, 2-octanone, 1-nonanone, 2-nonanone, acetone, 4-heptanone, 1-hexanone, 2-hexanone, diisobutyl ketone, phenylacetone, methyl ethyl ketone, methyl isobutyl ketone, acetylacetone, acetonylacetone, ionone, diacetonyl alcohol, acetylcarbinol, acetophenone, methyl naphthyl ketone, or methyl amyl ketone is preferable.

As the cyclic ketone, methylcyclohexanone, isophorone, or cyclohexanone is preferable.

As the lactone, γ-butyrolactone (γ-BL) is preferable.

As the alkylene carbonate, propylene carbonate is preferable.

In addition to the above-described components, an ester-based solvent having 7 or more (preferably 7 to 14, more preferably 7 to 12, and still more preferably 7 to 10) carbon atoms and having 2 or less heteroatoms is preferably used.

Preferred examples of the ester-based solvent having 7 or more carbon atoms and 2 or less heteroatoms include amyl acetate, 2-methylbutyl acetate, 1-methylbutyl acetate, hexyl acetate, pentyl propionate, hexyl propionate, butyl propionate, isobutyl isobutyrate, heptyl propionate, and butyl butanoate, and isoamyl acetate is particularly preferably used.

In addition, a solvent having a flash point (hereinafter, also referred to as fp) of 30° C. or higher is also preferably used. As such a solvent, propylene glycol monomethyl ether (fp: 47° C.), ethyl lactate (fp: 53° C.), ethyl 3-ethoxypropionate (fp: 49° C.), methyl amyl ketone (fp: 42° C.), cyclohexanone (fp: 30° C.), pentyl acetate (fp: 45° C.), methyl 2-hydroxyisobutyrate (fp: 45° C.), γ-butyrolactone (fp: 101° C.), or propylene carbonate (fp: 132° C.) is preferable. Among them, propylene glycol monoethyl ether, ethyl lactate (EL), pentyl acetate, or cyclohexanone is more preferable, and propylene glycol monoethyl ether or ethyl lactate is particularly preferable. The “flash point” herein means a value described in a reagent catalog of Tokyo Chemical Industry Co., Ltd. or Sigma-Aldrich Co. LLC.

As the solvent, at least one selected from the group consisting of water, propylene glycol monomethyl ether acetate (PGMEA), ethoxyethyl propionate, cyclohexanone, 2-heptanone, γ-butyrolactone, butyl acetate, propylene glycol monomethyl ether (PGME), ethyl lactate, and 4-methyl-2-pentamol is more preferable, and at least one selected from the group consisting of PGMEA and PGME is still more preferable.

### Ultraviolet Absorber

The composition for forming an imprint pattern according to the embodiment of the present invention may contain an ultraviolet absorber.

The ultraviolet absorber absorbs a leaked light (flare light) generated during exposure to suppress a reaction light from reaching the photopolymerization initiator, and plays a role of suppressing the reaction of the composition for forming an imprint pattern at a low exposure amount.

Examples of the type of the ultraviolet absorber include benzotriazole-based, triazine-based, cyanoacrylate-based, benzophenone-based, and benzoate-based.

A content of the ultraviolet absorber is preferably 0.01% to 5% by mass and more preferably 0.02% to 3% by mass. The ultraviolet absorber may be used alone or in combination of a plurality thereof. In a case where a plurality thereof is used, it is preferable that the total amount thereof is within the above-described range.

### Other Components

Other components may also be used in the composition for forming an imprint pattern according to the embodiment of the present invention. For example, the composition for forming an imprint pattern according to the embodiment of the present invention may include a sensitizer, an antioxidant, and the like. A content thereof is not particularly limited, but may be appropriately blended in an amount of approximately 0.01% to 20% by mass in the total solid content of the composition.

### Physical Properties

In a case where the composition for forming an imprint pattern is applied by an ink jet method, a viscosity of the composition for forming an imprint pattern at 23° C. is preferably 20 mPa·s or lower, more preferably 15 mPa·s or lower, still more preferably 11 mPa·s or lower, and even more preferably 9 mPa·s or lower. The lower limit of the above-described viscosity is not particularly limited, but is preferably 5 mPa·s or greater.

In a case where the composition for forming an imprint pattern is applied by a spin coating method, a viscosity of the composition for forming an imprint pattern at 23° C. is preferably 20 mPa·s or lower, more preferably 15 mPa·s or lower, still more preferably 11 mPa·s or lower, and even more preferably 9 mPa·s or lower. The lower limit of the above-described viscosity is not particularly limited, but is preferably 6 mPa·s or greater and more preferably 5 mPa·s or greater.

A viscosity of the composition for forming an imprint pattern in a case where the solvent is removed (that is, a viscosity of drying) at 23° C. is preferably 500 mPa·s or lower, more preferably 400 mPa·s or lower, still more preferably 300 mPa·s or lower, and even more preferably 250 mPa·s or lower. The lower limit of the above-described viscosity is not particularly limited, but is preferably 10 mPa·s or greater and more preferably 20 mPa·s or greater.

The viscosity is measured, for example, according to the following method.

The viscosity is measured using an E-type rotational viscometer RE85L manufactured by TOKI SANGYO CO., LTD, and a standard cone rotor (1° 34′×R24) in a state where a temperature of a sample cup is adjusted to 23° C. The unit is mPa·s. Other details regarding the measurement are in accordance with JIS Z 8803:2011. Two samples are produced for one level and are respectively measured three times. An arithmetic mean value of a total of six times is adopted as an evaluation value.

A surface tension (γResist) of the composition for forming an imprint pattern at 23° C. is preferably 28 mN/m or greater, more preferably 30 mN/m or greater, and still more preferably 32.0 mN/m or greater. By using the composition for forming an imprint pattern which has high surface tension, a capillary force is increased and thus high-speed filling of a mold pattern with the composition for forming an imprint pattern is possible. The upper limit value of the surface tension is not particularly limited, but from the viewpoint of imparting ink jet suitability, is preferably 40 mN/m or lower and more preferably 38 mN/m or lower, and may be 36 mN/m or lower. The surface tension of the composition for forming an imprint pattern is measured according to the following method.

The surface tension is measured at 23° C. using a surface tensiometer SURFACE TENS-IOMETER CBVP-A3 manufactured by Kyowa Interface Science Co., LTD. and a glass plate. The unit is mN/m. Two samples are produced for one level and are respectively measured three times. An arithmetic mean value of a total of six times is adopted as an evaluation value.

In the composition for forming an imprint pattern according to the embodiment of the present invention, a difference between a surface tension of the total solid content thereof and a surface tension of components of the total solid content of the composition for firming an imprint pattern excluding the release agent is preferably 1.5 mN/m or lower, more preferably 1.0 mN/m or lower, and still more preferably 0.8 mN/m or lower. The lower limit value thereof is preferably, for example, 0.01 mN/n or greater, and further 0.1 mN/m or greater. As this difference is smaller, a compatibility of the release agent in the composition for firming an imprint pattern is improved, and thus a homogeneous cured film can be formed.

An Ohnishi parameter of the composition for forming an imprint pattern is preferably 5 or less, more preferably 4 or less, and still more preferably 3.7 or less. The lower limit value of the Ohnishi parameter of the composition for forming an imprint pattern is not particularly specified, but may be, for example, 1 or greater or further 2 or greater.

For non-volatile components of the composition for forming an imprint pattern, the Ohnishi parameter can be determined by substituting the number of carbon atoms, the number of hydrogen atoms, and the number of oxygen atoms in all the constituent components into the following expression, respectively.

Ohnishi parameter=Sum of number of carbon atoms, number of hydrogen atoms, and number of oxygen atom/(Number of carbon atoms−Number of oxygen atoms)

In the composition for forming an imprint pattern according to the embodiment of the present invention, from the viewpoint of mold durability, the total amount of a metal atom and a metal ion is preferably 0.1% by mass or lower, more preferably 0.01% by mass or lower, and still more preferably 0.001% by mass or lower with respect to the total solid content of the composition for forming an imprint pattern.

The lower limit of the above-described total amount thereof is not particularly limited and may be 0% by mass.

The above-described metal atom and metal ion are included in the composition for forming an imprint pattern, for example, as a metal complex, a metal salt compound, and other impurities derived from each component.

The metal is not particularly limited, and examples thereof include iron, copper, titanium, lead, sodium, potassium, calcium, magnesium, manganese, aluminum, lithium, chromium, nickel, tin, zinc, arsenic, silver, gold, cadmium, cobalt, vanadium, and tungsten.

In the composition for forming an imprint pattern according to the embodiment of the present invention, from the viewpoint of mold durability, the total amount of an inorganic compound is preferably 1% by mass or lower, more preferably 0.1% by mass or lower, and still more preferably 0.01% by mass or lower with respect to the total solid content of the composition for forming an imprint pattern.

The lower limit of the above-described total amount thereof is not particularly limited and may be 0% by mass.

The inorganic compound is not particularly limited, and examples thereof include an inorganic colorant such as an inorganic pigment, semimetal particles such as silica particles, and metal particles such as titanium oxide particles.

In the composition for forming an imprint pattern according to the embodiment of the present invention, from the viewpoint of mold durability, the total amount of a salt compound is preferably 1% by mass or lower, more preferably 0.1% by mass or lower, and still more preferably 0.01% by mass or lower with respect to the total solid content of the composition for forming an imprint pattern.

The lower limit of the above-described total amount thereof is not particularly limited and may be 0% by mass.

The salt compound is not particularly limited, and examples thereof include a compound which is a component corresponding to a colorant, an acid generator, a polymerization initiator, a polymerizable compound, a resin, a polymerization inhibitor, a surfactant, and the like, and includes a salt structure.

The above-described salt structure is not particularly limited, and examples thereof include a single salt structure, a double salt structure, and a complex salt structure.

### Preparation Method of Composition for Forming Imprint Pattern

The composition for forming an imprint pattern according to the embodiment of the present invention is obtained by mixing the respective components.

The composition for forming an imprint pattern according to the embodiment of the present invention may be prepared by mixing the respective components and then filtering the liquid mixture with a filter. The filtration with a filter is preferably performed after the raw materials for the composition for forming an imprint pattern are mixed.

The above-described filtration with a filter may be performed only once or twice or more.

For example, for the purpose of reducing the total amount of the above-described metal atom and metal ion, the content of the above-described inorganic compound, and the like, the filtration can also be performed twice or more with filters having different material types or pore diameters.

Moreover, for the purpose of removing the above-described salt component, an ion exchange resin may be used.

### Preservation Container

As a storage container of the composition for forming an imprint pattern used in the present invention, a storage container well known in the related art can be used. Moreover, as the storage container, for the purpose of suppressing impurities from being mixed into a raw material or a composition, a multilayer bottle having a container inner wall made of six layers of six kinds of resins or a bottle having a seven-layer structure of six kinds of resins is also preferably used. Examples of such a container include the container described in JP2015-123351A.

### Cured Substance and Imprint Pattern Producing Method

An imprint pattern producing method according to an embodiment of the present invention includes an applying step of applying the composition for forming an imprint pattern according to the embodiment of the present invention to a member to be applied, which is selected from the group consisting of a support and a mold, a contact step of contacting a member which is not selected as the member to be applied from the group consisting of the support and the mold with the composition for forming an imprint pattern as a contact member, a curing step of forming a cured substance with the composition for forming an imprint pattern, and a peeling step of peeling off the cured substance from the mold.

### Applying Step

The imprint pattern producing method according to the embodiment of the present invention includes an applying step of applying the composition for forming an imprint pattern according to the embodiment of the present invention to a member to be applied, which is selected from the group consisting of a support and a mold.

In the applying step, one member selected from the group consisting of the support and the mold is selected as the member to be applied, and the composition for forming an imprint pattern according to the embodiment of the present invention is applied to the selected member to be applied.

Among the support and the mold, one is selected as the applied member and the other is a contact member.

That is, in the applying step, the composition for forming an imprint pattern according to the embodiment of the present invention may be applied to the support and then brought into contact with the mold, or may be applied to the mold and then brought into contact with the support (may have a closely adhesive layer or the like described later).

### Support

As the support, reference can be made to the description in paragraph 0103 of JP2010-109092A (the corresponding US application is the specification of US2011/0199592A), the contents of which are incorporated in the present specification. Specific examples thereof include a silicon substrate, a glass substrate, a sapphire substrate, a silicon carbide substrate, a gallium nitride substrate, a metal aluminum substrate, an amorphous aluminum oxide substrate, a polycrystalline aluminum oxide substrate, and a substrate made of GaAsP, GaP, AlGaAs, InGaN, GaN, AlGaN, ZnSe, AlGaInP, or ZnO. Furthermore, specific examples of a material for the glass substrate include aluminosilicate glass, aluminoborosilicate glass, and barium borosilicate glass. In the present invention, as the substrate, a silicon substrate is preferable.

It is preferable that the above-described support is a member including a closely adhesive layer on a surface on a side to which the composition for forming an imprint pattern is applied.

The closely adhesive layer is preferably a closely adhesive layer formed by applying a composition for forming a closely adhesive layer, which will be described later, to the support.

Moreover, the above-described support may further include a liquid film described later on a surface of the closely adhesive layer opposite to the support.

The liquid film is preferably a liquid film formed by applying a composition for forming a liquid film, which will be described later, to the closely adhesive layer.

As the above-described closely adhesive layer, the closely adhesive layers described in paragraphs 0017 to 0068 of JP2014-024322A, paragraphs 0016 to 0044 of JP2013-093552A, JP2014-093385A, JP2013-202982A, and the like can be used, the contents of which are incorporated in the present specification.

### Mold

In the present invention, the mold is not particularly limited. Regarding the mold, reference can be made to the description in paragraphs 0105 to 0109 of JP2010-109092A (the corresponding US application is the specification of US2011/0199592A), the contents of which are incorporated in the present specification. As the mold used in the present invention, a quartz mold is preferable. A pattern (line width) of the mold used in the present invention preferably has a size of 50 nm or less. The pattern of the mold can be formed according to a desired processing accuracy, for example, by photolithography, an electron beam drawing method, or the like, but in the present invention, a mold pattern producing method is not particularly limited.

### Applying Method

A method for applying the composition for forming an imprint pattern according to the embodiment of the present invention to the member to be applied is not particularly specified, and generally well-known application methods can be adopted. Examples thereof include a dip coating method, an air knife coating method, a curtain coating method, a wire bar coating method, a gravure coating method, an extrusion coating method, a spin coating method, a slit scanning method, and an ink jet method.

Among them, preferred examples thereof include an ink jet method and a spin coating method.

Moreover, the composition for forming an imprint pattern may be applied through multiple applying.

In a method of arranging liquid droplets by the ink jet method, an amount of the liquid droplets is preferably approximately 1 to 20 pL, and the liquid droplets are preferably arranged on the surface of a substrate at an interval between liquid droplets. The interval between liquid droplets may be appropriately set according to the amount of the liquid droplets, and is preferably an interval of 10 to 1,000 μm. In a case of the ink jet method, the interval between liquid droplets is an arrangement interval between ink jet nozzles.

The ink jet method has an advantage that a loss of the composition for forming an imprint pattern is small.

Specific examples of the method for applying the composition for forming an imprint pattern by the ink jet method include the methods described in JP2015-179807A, WO2016/152597A, and the like, and the methods described in these documents can also be suitably used in the present invention.

On the other hand, the spin coating method has an advantage that the coating process is highly stable and the choice of materials which can be used is expanded.

Specific examples of the method for applying the composition for forming an imprint pattern by the spin coating method include the methods described in JP2013-095833A, JP2015-071741A, and the like, and the methods described in these documents can also be suitably used in the present invention.

### Drying Step

Moreover, the imprint pattern producing method according to the embodiment of the present invention may further include a drying step of drying the composition for forming an imprint pattern according to the embodiment of the present invention applied in the applying step.

In particular, in a case where a composition including a solvent is used as the composition for forming an imprint pattern according to the embodiment of the present invention, it is preferable that the imprint pattern producing method according to the embodiment of the present invention includes the drying step.

In the drying step, at least a part of the solvent included in the composition for forming an imprint pattern according to the embodiment of the present invention applied is removed.

A drying method is not particularly limited, and drying by heating, drying by blowing air, or the like can be used without particular limitation, but drying by heating is preferable.

A heating unit is not particularly limited, and a well-known hot plate, oven, infrared heater, or the like can be used.

In the present invention, a layer formed from the composition for forming an imprint pattern after the applying step and the drying step performed as necessary and before the contact step is also referred to as a “pattern forming layer”.

### Contact Step

The imprint pattern producing method according to the embodiment of the present invention includes a contact step of contacting a member which is not selected as the member to be applied from the group consisting of the support and the mold with the composition for forming an imprint pattern (pattern forming layer) as a contact member.

In a case where the support is selected as the applied member in the above-described applying step, in the contact step, the mold, which is the contact member, is brought into contact with the surface of the support to which the composition for forming an imprint pattern according to the embodiment of the present invention is applied (surface on which the pattern forming layer is formed).

In a case where the mold is selected as the applied member in the above-described applying step, in the contact step, the support, which is the contact member, is brought into contact with the surface of the mold to which the composition for forming an imprint pattern according to the embodiment of the present invention is applied (surface on which the pattern forming layer is formed).

That is, by the contact step, the composition for forming an imprint pattern according to the embodiment of the present invention is present between the applied member and the contact member.

Details of the support and the mold are as described above.

In a case where the composition for forming an imprint pattern according to the embodiment of the present invention (pattern forming layer) which is applied to the applied member is brought into contact with the contact member, a pressing pressure is preferably 1 MPa or lower. By setting the pressing pressure to 1 MPa or lower, the support or the mold is less likely to be deformed and thus the pattern accuracy tends to be improved. Moreover, also from the viewpoint that a device tends to be miniaturized due to low pressing force, the above-described range is preferable.

In addition, it is also preferable that the contact between the pattern forming layer and the contact member is performed under an atmosphere including a helium gas, a condensable gas, or both a helium gas and a condensable gas.

### Curing Step

The imprint pattern producing method according to the embodiment of the present invention includes a curing step of forming a cured substance with the composition for forming an imprint pattern.

The curing step is performed after the above-described contact step and before the above-described peeling step.

A cured substance according to an embodiment of the present invention is a cured substance obtained by curing the composition for forming an imprint pattern according to the embodiment of the present invention, and is preferably a cured substance obtained by the curing step. Moreover, the above-described cured substance is preferably a cured substance in which the mold has been peeled off by the peeling step described later.

Examples of a curing method include curing by heating and curing by exposure, which may be determined according to the type of the polymerization initiator included in the composition for forming an imprint pattern, and curing by exposure is preferable.

For example, in a case where the above-described polymerization initiator is a photopolymerization initiator, the composition for forming an imprint pattern can be cured by performing exposure in the curing step.

An exposure wavelength is not particularly limited, and may be determined according to the polymerization initiator. For example, ultraviolet light or the like can be used.

An exposure light source may be determined according to the exposure wavelength, and examples thereof include g-rays (wavelength: 436 nm), h-rays (wavelength: 405 nm), i-rays (wavelength: 365 nm), broadband light (light including at least two wavelengths of light selected from the group consisting of three wavelengths of g-rays, h-rays, and i-rays; examples thereof include a high-pressure mercury lamp in a case where an optical filter is not used), semiconductor laser (wavelength: 830 nm, 532 nm, 488 nm, 405 nm and the like), metal halide lamp, excimer laser, KrF excimer laser (wavelength: 248 nm), ArF excimer laser (wavelength: 193 nm), F₂ excimer laser (wavelength: 157 nm), extreme ultraviolet rays (EUV; wavelength: 13.6 nm), and electron beam.

Among them, preferred examples thereof include exposure using i-rays or broadband light.

An irradiation amount (exposure amount) during the exposure may be sufficiently larger than the minimum irradiation amount required for curing the composition for forming an imprint pattern. The irradiation amount required for curing the composition for firming an imprint pattern can be appropriately determined by examining consumption or the like of an unsaturated bond of the composition for forming an imprint pattern.

The exposure amount is, for example, preferably in a range of 5 to 1,000 mJ/cm² and more preferably in a range of 10 to 500 mJ/cm².

An exposure illuminance is not particularly limited and may be selected depending on a relationship with the light source, but is preferably in a range of 1 to 500 mW/cm² and more preferably in a range of 10 to 400 mW/cm².

An exposure time is not particularly limited and may be determined in consideration of the exposure illuminance according to the exposure amount, but is preferably 0.01 to 10 seconds and more preferably 0.5 to 1 second.

A temperature of the substrate during the exposure is usually room temperature, but in order to increase reactivity, the exposure may be performed while heating. Since setting a vacuum state as a stage prior to the exposure is effective in preventing air hubbies from being mixed, suppressing a decrease in reactivity due to oxygen mixing, and improving adhesiveness between the mold and the composition for forming an imprint pattern, the exposure may be performed in a vacuum state. Moreover, a preferred degree of vacuum during the light irradiation is in a range of 10⁻¹ Pa to normal pressure.

After the exposure, as necessary, the composition for forming an imprint pattern after the exposure may be heated. A heating temperature is preferably 150° C. to 280° C. and more preferably 200° C. to 250° C. Moreover, a heating time is preferably 5 to 60 minutes and more preferably 15 to 45 minutes.

In addition, in the curing step, only the heating step may be performed without exposure. For example, in a case where the above-described polymerization initiator is a thermal polymerization initiator, the composition for forming an imprint pattern can be cured by performing heating in the curing step. A preferred aspect of the heating temperature and heating time in this case are the same as in the heating temperature and heating time in the case of heating after the above-described exposure.

A heating unit is not particularly limited, and examples thereof include the same heating unit as in the heating of the above-described drying step.

### Peeling Step

The imprint pattern producing method according to the embodiment of the present invention includes a peeling step of peeling off the cured substance from the mold.

By the peeling step, the cured substance obtained in the curing step is peeled off from the mold, and a cured substance in a patterned shape (also referred to as a “cured substance pattern”) to which the pattern of the mold is transferred can be obtained. The obtained cured substance pattern can be used for various uses as described later. In the present invention, the pattern producing method is particularly advantageous in that a fine cured substance pattern of a nano order can be formed, and a cured substance pattern having a size of 50 nm or lower and particularly 30 nm or lower can also be formed. The lower limit value of the size of the cured substance pattern formed by the pattern producing method according to the embodiment of the present invention is not particularly specified, but can be, for example, 1 nm or greater.

A peeling method is not particularly limited, and for example, the peeling can be performed by using a mechanical peeling device or the like known in the imprint pattern producing method.

### Evaluation Step

It is preferable that the imprint pattern producing method according to the embodiment of the present invention includes a step (also referred to as an “evaluation step”) of evaluating a transparency of the mold using a visible light having a wavelength at which the specific dye has an absorption after the peeling step.

Since the composition for forming an imprint pattern according to the embodiment of the present invention includes the specific dye, by evaluating the transparency of the mold, it is possible to estimate whether or not the composition for forming an imprint pattern remains in the mold and a residual amount thereof.

Specific examples thereof include a method in which, for the molds before the applying step, the contact step, the curing step, and the peeling step, a transmittance of visible light having a wavelength near the maximal absorption wavelength of the specific dye included in the composition for forming an imprint pattern is measured, and a difference in transmittance by measuring the transmittance again after the peeling step is calculated.

Moreover, the above-described evaluation can be performed, for example, by the same method as the “Evaluation of mold transparency” in Examples described later.

### Method for Manufacturing Device and Application of Cured Substance Pattern

A method for manufacturing a device according to an embodiment of the present invention includes the imprint pattern producing method according to the embodiment of the present invention.

Specifically, a pattern (cured substance pattern) formed by the imprint pattern producing method according to the embodiment of the present invention can be used in a method for manufacturing a device such as a permanent film used in a liquid crystal display device (LCD) or the like, or an etching resist (mask for lithography) for manufacturing a semiconductor element.

In particular, the present invention discloses a method for manufacturing a circuit board, which includes a step of obtaining a pattern (cured substance pattern) by the imprint pattern producing method according to the embodiment of the present invention, and a method for manufacturing a device including the circuit board. The method for manufacturing a circuit board according to the preferred embodiment of the present invention may further include a step of performing etching or ion implantation on the substrate using the pattern (cured substance patter)) obtained by the above-described pattern forming as a mask and a step of forming an electronic member. The above-described circuit board is preferably a semiconductor element. That is, the present invention discloses a method for manufacturing a semiconductor device, including the imprint pattern producing method according to the embodiment of the present invention. Further, the present invention discloses a method for manufacturing a device, which includes a step of obtaining a circuit board by the above-described method for manufacturing a circuit board and a step of connecting the circuit board and a control mechanism which controls the circuit board.

Moreover, by forming a grid pattern on a glass substrate of a liquid crystal display device using the imprint pattern producing method according to the embodiment of the present invention, a polarizing plate having low reflection or absorption and a large screen size (for example, 55 inches, or greater than 60 inches) can be manufactured at a low cost. That is, the present invention discloses a method for manufacturing a polarizing plate and a method for manufacturing a device including the polarizing plate, which include the imprint pattern producing method according to the embodiment of the present invention. For example, the polarizing plate described in JP2015-132825A or WO2011/132649A can be manufactured. Furthermore, 1 inch is 25.4 mm.

The pattern (cured substance pattern) manufactured by the imprint pattern producing method according to the embodiment of the present invention is also useful as an etching resist (mask for lithography). That is, the present invention discloses a method for manufacturing a device in which the obtained cured substance pattern is used as an etching resist, including the imprint pattern producing method according to the embodiment of the present invention.

In a case where the cured substance pattern is used as an etching resist, examples thereof include an aspect in which, first, a pattern (cured substance pattern) is formed by applying the imprint pattern producing method according to the embodiment of the present invention on a substrate, and the obtained cured substance pattern is used as an etching mask to etch the substrate. By performing etching with an etching gas such as hydrogen fluoride or the like in a case of wet etching and CF₄ or the like in a case of dry etching, a pattern can be formed on the substrate along the shape of the desired cured substance pattern.

Moreover, the pattern (cured substance pattern) produced by the imprint pattern producing method according to the embodiment of the present invention can be also preferably used for producing a recording medium such as a magnetic disc, a light-receiving element such as a solid-state imaging element, a light emitting element such as a light emitting diode (LED) and organic electroluminescence (organic EL), an optical device such as a liquid crystal display device (LCD), an optical component such as a diffraction grating, a relief hologram, an optical waveguide, an optical filter, and a microlens array, a member for flat panel display such as a thin film transistor, an organic transistor, a color filter, an antireflection film, a polarizing plate, a polarizing element, an optical film, and a column material, a nanobiodevice, an immunoassay chip, a deoxyribonucleic acid (DNA) separation chip, a microreactor, photonic liquid crystal, or a guide pattern for fine pattern formation (directed self-assembly, DSA) using self-assembly of block copolymers.

That is, the present invention discloses a method for manufacturing these device, including the imprint pattern producing method according to the embodiment of the present invention.

### Composition for Forming Closely Adhesive Layer

As described above, by providing the closely adhesive layer between the support and the composition for forming an imprint pattern, effects such as improvement in adhesiveness between the substrate and a composition layer for forming an imprint pattern can be achieved. In the present invention, the closely adhesive layer can be obtained by applying the composition for forming a closely adhesive layer to the substrate and then curing the composition, in the same manner as the composition for forming an imprint pattern. Hereinafter, each component of the composition for forming a closely adhesive layer will be described.

The composition for forming a closely adhesive layer includes a curable component. The curable component is a component constituting the closely adhesive layer, and may be any one of a high-molecular-weight component (for example, a molecular weight is more than 1,000) or a low-molecular-weight component (for example, a molecular weight is less than 1,000). Specific examples thereof include a resin and a crosslinking agent. Each of these components may be used alone or in combination of two or more kinds thereof.

A total content of the curable components in the composition for forming a closely adhesive layer is not particularly limited, but is preferably 50% by mass or greater in the total solid content, more preferably 70% by mass or greater in the total solid content, and still more preferably 80% by mass or greater in the total solid content. The upper limit thereof is not particularly limited, but is preferably 99.9% by mass or lower.

A concentration of the curable component in the composition for forming a closely adhesive layer (including a solvent) is not particularly limited, but is preferably 0.01% by mass or greater, more preferably 0.05% by mass or greater, and still more preferably 0.1% by mass or greater. The upper limit thereof is preferably 10% by mass or lower, more preferably 5% by mass or lower, still more preferably 1% by mass or lower, and even more preferably lower than 1% by mass.

### Resin

As the resin in the composition for forming a closely adhesive layer, a well-known resin can be widely used. The resin used in the present invention preferably has at least one of a radically polymerizable group or a polar group, and more preferably has both a radically polymerizable group and a polar group.

By having the radically polymerizable group, a closely adhesive layer having excellent hardness can be obtained. Moreover, by having the polar group, adhesiveness to a substrate is improved. Furthermore, in a case where a crosslinking agent is formulated, a crosslinking structure formed after curing is further firmed, and thus hardness of the obtained closely adhesive layer can be improved.

The radically polymerizable group preferably includes an ethylenically unsaturated bond-containing group. Examples of the ethylenically unsaturated bond-containing group include a (meth)acryloyl group (preferably a (meth)acryloyloxy group and a (meth)acryloylamino group), a vinyl group, a vinyloxy group, an allyl group, a methylallyl group, a propenyl group, a butenyl group, a vinylphenyl group, and a cyclohexenyl group, and a (meth)acryloyl group or a vinyl group is preferable, a (meth)acryloyl group is more preferable, and a (meth)acryloyloxy group is still more preferable. The ethylenically unsaturated bond-containing group defined here is referred to as Et.

Furthermore, the polar group is preferably at least one kind of an acyloxy group, a carbamoyloxy group, a sulfonyloxy group, an acyl group, an alkoxycarbonyl group, an acylamino group, a carbamoyl group, an alkoxycarbonylamino group, a sulfonamide group, a phosphoric acid group, a carboxy group, or a hydroxy group, more preferably at least one kind of an alcoholic hydroxy group, a phenolic hydroxy group, or a carboxy group, and still more preferably an alcoholic hydroxy group or a carboxy group. The polar group defined here is referred to as a polar group Po. The polar group is preferably a nonionic group.

The resin in the composition for forming a closely adhesive layer may further include a cyclic ether group. Examples of the cyclic ether group include an epoxy group and an oxetanyl group, and an epoxy group is preferable. The cyclic ether group defined here is referred to as a cyclic ether group Cyt.

Examples of the resin include a (meth)acrylic resin, a vinyl resin, a novolac resin, a phenol resin, a melamine resin, a urea resin, an epoxy resin, and a polyimide resin, and at east one kind of a (meth)acrylic resin, a vinyl resin, or a novolac resin is preferable.

A weight-average molecular weight of the resin is preferably 4,000 or more, more preferably 6,000 or more, and still more preferably 8,000 or more. The upper limit thereof is preferably 1,000,000 or less and may be 500,000 or less.

The resin preferably has at least one of constitutional units represented by Formulae (1) to (3).

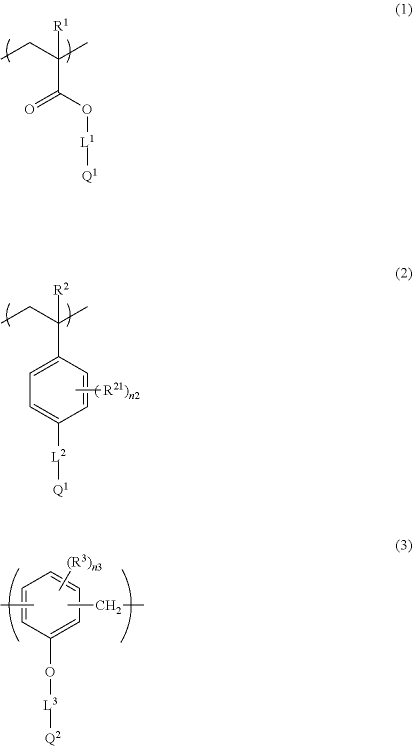

In the formulae, R¹ and R² are each independently a hydrogen atom or a methyl group. R² and R³ are each independently a substituent. L¹, L², and L³ are each independently a single bond or a linking group. n2 is an integer of 0 to 4. n3 is an integer of 0 to 3. Q¹ is an ethylenically unsaturated bond-containing group or a cyclic ether group. Q² is an ethylenically unsaturated bond-containing group, a cyclic ether group, or a polar group.

R¹ and R² are each preferably a methyl group.

R²¹ and R³ are each independently preferably the substituent T.

In a case where there is a plurality of R²¹'s, R²¹'s may be linked to each other to form a cyclic structure. In the present specification, the linking is meant to include not only an aspect in which groups are continued by bonding but also an aspect in which groups lose some atoms and are fused (condensed). Moreover, unless otherwise specified, an oxygen atom, a sulfur atom, and a nitrogen atom (amino group) may be included in the linking cyclic structure. Examples of the formed cyclic structure include an aliphatic hydrocarbon ring (groups exemplified below are referred to as a ring Cf) (for example, a cyclopropyl group, a cyclobutyl group, a cyclopentyl group, a cyclohexyl group, a cyclopropenyl group, a cyclobutenyl group, a cyclopentenyl group, a cyclohexenyl group, and the like), an aromatic hydrocarbon ring (rings exemplified below are referred to as a ring Cr) (a benzene ring, a naphthalene ring, an anthracene ring, a phenanthrene ring, and the like), a nitrogen-containing heterocycle (rings exemplified below are referred to as a ring Cn) (for example, a pyrrole ring, an imidazole ring, a pyrazole ring, a pyridine ring, a pyrroline ring, a pyrrolidine ring, an imidazolidine ring, a pyrazolidine ring, a piperidine ring, a piperazine ring, a morpholine ring, and the like), an oxygen-containing heterocycle (rings exemplified below are referred to as a ring Co) (a furan ring, a pyran ring, an oxirane ring, an oxetane ring, a tetrahydrofiiran ring, a tetrahydropyran ring, a dioxane ring, and the like), and a sulfur-containing heterocycle (rings exemplified below are referred to as a ring Cs) (a thiophene ring, a thiirane ring, a thietane ring, a tetrahydrothiophene ring, a tetrahydrothiopyran ring, and the like).

In a case where there is a plurality of R³'s, R³'s may be linked to each other to form a cyclic structure. Examples of the formed cyclic structure include the ring Cf, the ring Cr, the ring Cn, the ring Co, and the ring Cs.

It is preferable that L¹, L², and L³ are each independently a single bond or a linking group L which will be described later. Among them, a single bond, or an alkylene group or an (oligo)alkyleneoxy group, which is defined as the linking group L, is preferable, and an alkylene group is more preferable. The linking group L preferably has the polar group Po as a substituent. Moreover, an aspect in which the alkylene group has a hydroxy group as a substituent is also preferable. In the present specification, the “(oligo)alkyleneoxy group” means a divalent linking group having one or more “alkyleneoxy” constitutional units. The number of carbon atoms in an alkylene chain in the constitutional unit may be the same or different for every constitutional unit.

n2 is preferably 0 or 1 and more preferably 0. n3 is preferably 0 or 1 and more preferably 0.

Q¹ is preferably the ethylenically unsaturated bond-containing group Et.

Q² is preferably a polar group, and preferably an alkyl group having an alcoholic hydroxy group.

The resin may further include at least one of a constitutional unit (11), a constitutional unit (21), or a constitutional unit (31). In particular, in the resin included in the present invention, the constitutional unit (11) is preferably combined with the constitutional unit (1), the constitutional unit (21) is preferably combined with the constitutional unit (2), and the constitutional unit (31) is preferably combined with the constitutional unit (3).

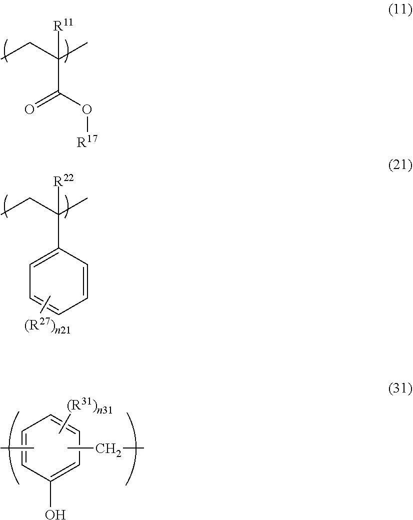

In the formulae, R¹¹ and R²² are each independently a hydrogen atom or a methyl group, R¹⁷ is a substituent, R²⁷ is a substituent. n21 is an integer of 0 to 5. R³¹ is a substituent, and n31 is an integer of 0 to 3.

R¹¹ and R²² are each preferably a methyl group.

R¹⁷ is preferably a group containing a polar group or a group containing a cyclic ether group. In a case where R¹⁷ is a group containing a polar group, R¹⁷ is preferably a group containing the polar group Po, and more preferably the polar group Po or the substituent T substituted with the polar group Po. In a case where R¹⁷ is a group containing a cyclic ether group, R¹⁷ is preferably a group containing the cyclic ether group Cyt, and more preferably the substituent T substituted with the cyclic ether group Cyt.

R²⁷ is a substituent, and at least one of R²⁷'s is preferably a polar group. The substituent is preferably the substituent T, n21 is preferably 0 or 1 and more preferably 0. In a case where there is a plurality of R²⁷'s, R²⁷'s may be linked to each other to form a cyclic structure. Examples of the formed cyclic structure include examples of the ring Cf, the ring Cr, the ring Cn, the ring Co, and the ring Cs.

R³¹ is preferably the substituent T. n31 is an integer of 0 to 3, preferably 0 or 1, and more preferably 0. In a case where there is a plurality of R³¹'s, R³¹'s may be linked to each other to form a cyclic structure. Examples of the formed cyclic structure include examples of the ring Cf, the ring Cr, the ring Cn, the ring Co, and the ring Cs.

Examples of the linking group L include an alkylene group (the number of carbon atoms is preferably 1 to 24, more preferably 1 to 12, and still more preferably 1 to 6), an alkenylene group (the number of carbon atoms is preferably 2 to 12, more preferably 2 to 6, and still more preferably 2 or 3), an (oligo)alkyleneoxy group (the number of carbon atoms in an alkylene group in one constitutional unit is preferably 1 to 12, more preferably 1 to 6, and still more preferably 1 to 3; and the repetition number is preferably 1 to 50, more preferably 1 to 40, and still more preferably 1 to 30), an arylene group (the number of carbon atoms is preferably 6 to 22, more preferably 6 to 18, and still more preferably 6 to 10), an oxygen atom, a sulfur atom, a sulfonyl group, a carbonyl group, a thiocarbonyl group, —NR^{N}—, and a linking group related to a combination thereof. The alkylene group, alkenylene group, and alkyleneoxy group may have the substituent T. For example, the alkylene group may have a hydroxy group.

A linking chain length of the linking group L is preferably 1 to 24, more preferably 1 to 12, and still more preferably 1 to 6. The linking chain length means the number of atoms positioned on the shortest path among the atomic groups involved in the linkage. For example, in a case of —CH₂—(C═O)—O—, the linking chain length is 3.

Furthermore, the alkylene group, alkenylene group, and (oligo)alkyleneoxy group, which are defined as the linking group L, may be chain-like or cyclic, or may be linear or branched.

It is preferable that as an atom constituting the linking group L, a carbon atom, a hydrogen atom, and as necessary, a heteroatom (at least one kind selected from an oxygen atom, a nitrogen atom, or a sulfur atom, and the like) are included. The number of carbon atoms in the linking group is preferably 1 to 24, more preferably 1 to 12, and still more preferably 1 to 6. The number of hydrogen atom may be determined according to the number of carbon atoms and the like. In a case of the number of heteroatoms, the numbers of the oxygen atoms, the nitrogen atoms, and the sulfur atoms are each independently preferably 0 to 12, more preferably 0 to 6, and still more preferably 0 to 3.

The resin may be synthesized by a conventional method. For example, a resin having the constitutional unit represented by Formula (1) can be appropriately synthesized by a well-known method for addition polymerization of olefin. A resin having the constitutional unit represented by Formula (2) can be appropriately synthesized by a well-known method for addition polymerization of styrene. A resin having the constitutional unit represented by Formula (3) can be appropriately synthesized by a well-known method for synthesis of a phenol resin.

The resin may be used alone or in combination of a plurality thereof.

As the resin as the curable component, in addition to the above-described resins, the resins described in paragraphs 0016 to 0079 of WO2016/152600A, paragraphs 0025 to 0078 of WO2016/148095A, paragraphs 0015 to 0077 of WO2016/031879A, and paragraphs 0015 to 0057 of WO2016/027843A can be used, the contents of which are incorporated in the present specification.

### Crosslinking Agent

The crosslinking agent in the composition for forming a closely adhesive layer is not particularly limited as long as the crosslinking agent advances curing by a crosslinking reaction. In the present invention, the crosslinking agent is preferably reacted with a polar group of a resin to form a crosslinking structure. By using such a crosslinking agent, the resin is more firmly bonded, and thus a firmer film can be obtained.

Examples of the crosslinking agent include an epoxy compound (compound having an epoxy group), an oxetanyl compound (compound having an oxetanyl group), an alkoxymethyl compound (compound having an alkoxymethyl group), a methylol compound (compound having a methylol group), and a blocked isocyanate compound (compound having a blocked isocyanate group), and an alkoxymethyl compound (compound having an alkoxymethyl group) can form a firm bond at a low temperature and thus is preferable.

### Other Components

The composition for forming a closely adhesive layer may include other components in addition to the above-described components.

Specifically, one or more kinds of a solvent, a thermal acid generator, an alkylene glycol compound, a polymerization initiator, a polymerization inhibitor, an antioxidant, a leveling agent, a thickener, a surfactant, or the like may be included. Regarding the above-described components, the respective components described in JP2013-036027A, JP2014-090133A, and JP2013-189537A can be used. Also regarding the content or the like, reference can be made to the description in the above-described publications.

### Solvent

In the present invention, the composition for forming a closely adhesive layer particularly preferably contains a solvent (hereinafter, also referred to as a “solvent for a closely adhesive layer”). The solvent is, for example, preferably a compound which is liquid at 23° C. and has a boiling point of 250° C. or lower. A content of the solvent for a closely adhesive layer in the composition for forming a closely adhesive layer is preferably 99.0% by mass or greater and more preferably 99.2% by mass or greater, and may be 99.4% by mass or greater. That is, the concentration of the total solid content in the composition for forming a closely adhesive layer is preferably 1% by mass or lower, more preferably 0.8% by mass or lower, and still more preferably 0.6% by mass or lower. Moreover, the lower limit value thereof is preferably greater than 0% by mass, more preferably 0.001% by mass or greater, still more preferably 0.01% by mass or greater, and even more preferably 0.1% by mass or greater. By setting the proportion of the solvent within the above-described range, a film thickness during film formation is kept thin, and thus pattern formability during etching processing tends to be improved.

Only one kind or two or more kinds of the solvents may be contained in the composition for forming a closely adhesive layer. In a case where two or more kinds thereof are contained, the total amount thereof is preferably within the above-described range.

A boiling point of the solvent for a closely adhesive layer is preferably 230° C. or lower, more preferably 200° C. or lower, still more preferably 180° C. or lower, even more preferably 160° C. or lower, and further still more preferably 130° C. or lower. The lower limit value thereof is preferably 23° C. or higher and more preferably 60° C. or higher. By setting the boiling point within the above-described range, the solvent can be easily removed from the closely adhesive layer, which is preferable.

The solvent for a closely adhesive layer is preferably an organic solvent. The solvent is preferably a solvent having any one or more of an ester group, a carbonyl group, a hydroxy group, or an ether group. Among them, it is preferable to use an aprotic polar solvent.

Examples of a preferred solvent among the solvents for a closely adhesive layer include alkoxy alcohol, propylene glycol monoalkyl ether carboxylate, propylene glycol monoalkyl ether, lactic acid ester, acetic acid ester, alkoxypropionic acid ester, chain-like ketone, cyclic ketone, lactone, and alkylene carbonate, and propylene glycol monoalkyl ether and lactone are particularly preferable.

### Thermal Acid Generator

The thermal acid generator is a compound which generates an acid by heating and advances crosslinking by the action of the acid. In a case of being used in combination with the crosslinking agent, a closely adhesive layer having higher hardness can be obtained. As the thermal acid generator, an organic onium salt compound in which a cationic component and an anionic component are paired is usually used. As the cationic component, for example, organic sulfonium, organic oxonium, organic ammonium, organic phosphonium, and organic iodonium can be mentioned. Moreover, as the anionic component, for example, BF⁴⁻, B(C₆F₅)⁴⁻, AsF⁶⁻, PF⁶⁻, CF₃SO₃⁻, C₄F₉SO₃³¹ , and (CF₃SO₂)₃C⁻ can be mentioned.

Specifically, reference can be made to the description in paragraphs 0243 to 0256 of JP2017-224660A and paragraph 0016 of JP2017-155091A, the contents of which are incorporated in the present specification.

A content of the thermal acid generator is preferably 0.01 to 10 parts by mass and more preferably 0,1 to 5 parts by mass, with respect to 100 parts by mass of the crosslinking agent. The thermal acid generator may be used alone or in combination of two or more kinds thereof in a case where two or more kinds thereof are used, the total amount thereof is preferably within the above-described range.

### Polymerization Initiator

The composition for forming a closely adhesive layer may contain a polymerization initiator and preferably contains at least one kind of a thermal polymerization initiator or a photopolymerization initiator. Moreover, it is not necessary that the composition for forming a closely adhesive layer contain the polymerization initiator. By containing the polymerization initiator, a reaction of a polymerizable group contained in the composition for forming a closely adhesive layer is promoted, and thus the adhesiveness tends to be improved. From the viewpoint that crosslinking reactivity with the composition for forming an imprint pattern is improved, a photopolymerization initiator is preferable. As the photopolymerization initiator, a radical polymerization initiator or a cationic polymerization initiator is preferable, and a radical polymerization initiator is more preferable. Moreover, in the present invention, a plurality of kinds of photopolymerization initiators may be used in combination.

As a photoradical polymerization initiator, well-known compounds can be optionally used. Examples thereof include a halogenated hydrocarbon derivative (for example, a compound having a triazine skeleton, a compound having an oxadiazole skeleton, a compound having a trihalomethyl group, and the like), an acylphosphine compound such as acylphosphine oxide, hexaarylbiimidazole, an oxime compound such as an oxime derivative, an organic peroxide, a thio compound, a ketone compound, an aromatic onium salt, ketoxime ether, an aminoacetophenone compound, hydroxyacetophenone, an azo-based compound, an azide compound, a metallocene compound, an organic boron compound, and an iron arene complex. For the details thereof, reference can be made to the description in paragraphs 0165 to 0182 of 11³2016-027357A, the contents of which are incorporated in the present specification.

Examples of the acylphosphine compound include 2,4,6-trimethylbenzoyl-diphenyl-phosphine oxide. Moreover, IRGACURE-819, IRGACURE 1173, and IRGACURE-TPO (trade names; all are manufactured by BASF SE), which are commercially available products, can be used.

In a case where the photopolymerization initiator used in the composition for forming a closely adhesive layer is formulated, a content thereof in the total solid content is, for example, 00001 to 5% by mass, preferably 0.0005% to 3% by mass, and more preferably 0.01% to 1% by mass. In a case where two or more kinds of photopolymerization initiators are used, the total amount thereof is within the above-described range.

### Composition for Forming Liquid Film

In addition, in the present invention, it is also preferable that a liquid film is formed on the closely adhesive layer by using a composition for forming a liquid film containing a radically polymerizable compound which is a liquid at 23° C. and 1 atm. In the present invention, the liquid film can be obtained by applying the composition for forming a liquid film onto the substrate and then drying the composition, in the same manner as the composition for forming an imprint pattern. By forming such a liquid film, there are effects that the adhesiveness between the substrate and the composition for forming an imprint pattern is further improved, and that the wettability of the composition for forming an imprint pattern on the substrate is also improved. Hereinafter, the composition for forming a liquid film will be described.

The viscosity of the composition for forming a liquid film is preferably 1,000 mPa·s or lower, more preferably 800 mPa·s or lower, still more preferably 500 mPa·s or lower, and even more preferably 100 mPa·s or lower. The lower limit value of the viscosity is not particularly limited, but can be, for example, 1 mPa·s or greater. The viscosity is measured according to the following method.

The viscosity is measured using an E-type rotational viscometer RE85L manufactured by TOKI SANGYO CO., LTD. and a standard cone rotor (1° 34′×R24) in a state where a temperature of a sample cup is adjusted to 23° C. The unit is mPa·s. Other details regarding the measurement are in accordance with JIS Z 8803:2011. Two samples are produced for one level and are respectively measured three times. An arithmetic mean value of a total of six times is adopted as an evaluation value.

### Radically Polymerizable Compound A

The composition for forming a liquid film contains a radically polymerizable compound (radically polymerizable compound. A) which is a liquid at 23° C. and 1 atm.

A viscosity of the radically polymerizable compound A at 23° C. is preferably 1 to 100,000 mPa·s. The lower limit thereof is preferably 5 mPa·s or greater and more preferably 11 mPa·s or greater. The upper limit thereof is preferably 1,000 mPa·s or lower and more preferably 600 mPa·s or lower.

The radically polymerizable compound A may be a monofunctional radically polymerizable compound having only one radically polymerizable group in one molecule, or a polyfunctional radically polymerizable compound having two or more radically polymerizable groups in one molecule. The monofunctional radically polymerizable compound and the polyfunctional radically polymerizable compound may be used in combination. Among them, for a reason of suppressing pattern collapse, the radically polymerizable compound A contained in the composition for funning a liquid film preferably includes a polyfunctional radically polymerizable compound, more preferably includes a radically polymerizable compound having two to five radically polymerizable groups in one molecule, still more preferably includes a radically polymerizable compound having two to four radically polymerizable groups in one molecule, and particularly preferably includes a radically polymerizable compound having two radically polymerizable groups in one molecule.

Furthermore, the radically polymerizable compound A preferably contains at least one of an aromatic ring (the number of carbon atoms is preferably 6 to 22, more preferably 6 to 18, and still more preferably 6 to 10) or an alicyclic ring (the number of carbon atoms is preferably 3 to 24, more preferably 3 to 18, and still more preferably 3 to 6), and more preferably contains an aromatic ring. The aromatic ring is preferably a benzene ring. Moreover, a molecular weight of the radically polymerizable compound A is preferably 100 to 900.

Examples of the radically polymerizable group of the radically polymerizable compound A include ethylenically unsaturated bond-containing groups, such as a vinyl group, an allyl group, and a (meth)acryloyl group, and a (meth)acryloyl group is preferable.

It is also preferable that the radically polymerizable compound A is a compound represented by Formula (I-1).

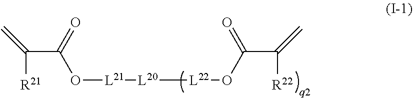

L²⁰ is a (1+q2)-valent linking group, and examples thereof include (1+q2)-valent linking groups which contains a group (the number of carbon atoms is preferably 1 to 12, more preferably 1 to 6, and still more preferably 1 to 3) having an alkane structure, a group (the number of carbon atoms is preferably 2 to 12, more preferably 2 to 6, and still more preferably 2 or 3) having an alkene structure, a group (the number of carbon atoms is preferably 6 to 22, more preferably 6 to 18, and still more preferably 6 to 10) having an aryl structure, a group (the number of carbon atoms is preferably 1 to 22, more preferably 1 to 18, and still more preferably 1 to 10, examples of a heteroatom include a nitrogen atom, a sulfur atom, and an oxygen atom, and a 5-membered ring, a 6-membered ring, or a 7-membered ring are preferable) having a heteroaryi structure, or a group obtained by combining these groups. Examples of the group in which two aryl groups are combined include groups having a structure such as biphenyl, diphenylalkane, biphenylene, and indene. Examples of a combination of the group having a heteroaryl structure and the group having an aryl structure include groups having a structure such as indole, benzimidazole, quinoxaline, and carbazole.

L²⁰ is preferably a linking group including at least one kind selected from a group having an aryl structure or a group having a heteroaryl structure, and more preferably a linking group including a group having an aryl structure.

R²¹ and R²² each independently represent a hydrogen atom or a methyl group.

L²¹ and L²² each independently represent a single bond or the linking group L, and a single bond or an alkylene group is preferable.

L²⁰ and L²¹ or L²² may be bonded to each other through or without through the linking group L to form a ring. L²⁰, L²¹ and L²² may have the above-described substituent T. A plurality of substituents T may be bonded to each other to form a ring. In a case where there are the plurality of substituents T, the plurality of substituents T may be the same as or different from each other.

q2 is an integer of 0 to 5, preferably an integer of 0 to 3, more preferably an integer of 0 to 2, still more preferably 0 or 1, and particularly preferably 1.

As the radically polymerizable compound A, the compounds described in paragraphs 0017 to 0024 and Examples of 11)2014-090133A, the compounds described in paragraphs 0024 to 0089 of JP2015-009171A, the compounds described in paragraphs 0023 to 0037 of JP2015-070145A, and the compounds described in paragraphs 0012 to 0039 of WO2016/152597A can also be used.

A content of the radically polymerizable compound A in the composition for forming a liquid film is preferably 0.01% by mass or greater, more preferably 0.05% by mass or greater, and still more preferably 0.1% by mass or greater. The upper limit thereof is preferably 10% by mass or lower, more preferably 5% by mass or lower, and still more preferably 1% by mass or lower.

The content of the radically polymerizable compound A in the solid content of the composition for forming a liquid film is preferably 50% by mass or greater, more preferably 75% by mass or greater, and still more preferably 90% by mass or greater. The upper limit thereof may be 100% by mass. The radically polymerizable compound A may be used alone or in combination of two or more kinds thereof. In a case where two or more kinds thereof are used, the total amount thereof is preferably within the above-described range.

Furthermore, it is also preferable that the solid content of the composition for forming a liquid film substantially consists of the radically polymerizable compound A. The case where the solid content of the composition for forming a liquid film substantially consists of the radically polymerizable compound A means that the content of the radically polymerizable compound A in the solid content of the composition for forming a liquid film is 99.9% by mass or greater, the content is more preferably 99.99% by mass or greater, and it is still more preferable that the solid content consists of the radically polymerizable compound A.

### Solvent

The composition for forming a liquid film preferably contains a solvent (hereinafter, referred to as a “solvent for a liquid film” in some cases). Examples of the solvent for a liquid film include the solvents described in the above-described section of the solvent for a closely adhesive layer, and these solvents can be used. A content of the solvent for a liquid film in the composition for forming a liquid film is preferably 90% by mass or greater and more preferably 99% by mass or greater, and may be 99.99% by mass or greater.

A boiling point of the solvent for a liquid film is preferably 230° C. or lower, more preferably 200° C. or lower, still more preferably 180° C. or lower, even more preferably 160° C. or lower, and further still more preferably 130° C. or lower. The lower limit value thereof is preferably 23° C. and more preferably 60° C. or higher. By setting the boiling point within the above-described range, the solvent can be easily removed from the liquid film, which is preferable.

### Radical Polymerization Initiator

The composition for forming a liquid film may contain a radical polymerization initiator. Examples of the radical polymerization initiator include a thermal radical polymerization initiator and a photoradical polymerization initiator, and a photoradical polymerization initiator is preferable. As a photoradical polymerization initiator, well-known compounds can be optionally used. Examples thereof include a halogenated hydrocarbon derivative (for example, a compound having a triazine skeleton, a compound having an oxadiazole skeleton, a compound having a trihalomethyl group, and the like), an acylphosphine compound, a hexaarylbiimidazole compound, an oxime compound, an organic peroxide, a thio compound, a ketone compound, an aromatic onium salt, an acetophenone compound, an azo compound, an azide compound, a metallocene compound, an organic boron compound, and an iron arene complex. For the details thereof, reference can be made to the description in paragraphs 0165 to 0182 of JP2016-027357A, the contents of which are incorporated in the present specification. Among them, an acetophenone compound, an acylphosphine compound, or an oxime compound is preferable. Examples of a commercially available product thereof include IRGACURE-OXE01, IRGACURE-OXE02, IRGACURE-127, IRGACURE-819, IRGACURE-379, IRGACURE-369, IRGACURE-754, IRGACURE-1800, IRGACURE-651, IRGACURE-907, IRGACURE-TPO, and IRGACURE-1173 (all manufactured by BASF SE), and Omnirad 184, Omnirad TPO H, Omnirad 819, and Omnirad 1173 (all manufactured by IGM Resins B.V.).

In a case where the radical polymerization initiator is contained, the content thereof with respect to the solid content of the composition for forming a liquid film is preferably 0.1% to 10% by mass, more preferably 1% to 8% by mass, and still more preferably 2% to 5% by mass. In a case where two or more kinds of the radical polymerization initiators are used, the total amount thereof is preferably within the above-described range.

### Other Components

The composition for forming a liquid film may include one or more kinds of a polymerization inhibitor, an antioxidant, a leveling agent, a thickener, a surfactant, or the like, in addition to the above-described components.

### Examples

Hereinafter, the present invention will be described in more detail with reference to Examples. The materials, the used amounts, the ratios, the treatment details, the treatment procedures, and the like shown in the following Examples can be appropriately modified without departing from the spirit of the present invention. Therefore, the scope of the present invention is not limited to the specific examples described below. In Examples, unless otherwise specified, “parts” and “%” are based on mass, and an environmental temperature (room temperature) in each step is 23° C.,

### Preparation of Composition for Forming Imprint Pattern

For each Example and each Comparative Example, various compounds described in the column of “Composition for forming imprint pattern” in Table 1 or Table 2 were mixed, and 4-hydroxy-2,2,6,6-tetramethylpiperidine-1-oxyl free radical (manufactured by Tokyo Chemical Industry Co., Ltd.) as a polymerization inhibitor was added thereto so that an amount thereof was 200 ppm by mass (0.02% by mass) with respect to the total amount of a polymerizable compound, thereby preparing a composition.

The content of each component other than a solvent is a content (part by mass) shown in Table 1 or Table 2. and as for the content of the solvent, the concentration of solid contents of each composition is set to the value described in the column of “Concentration of solid contents (% by mass)” in Table 1 or Table 2. The numerical value described in the column of “Solvent” is a content ratio (% by mass) of each solvent, and the description of “100” means that the solvent was used alone. Moreover, in each composition, a component described as “-” was not added.

The composition was filtered through a 0.02 μm Nylon filter and a 0.001 μm ultra-high-molecular-weight polyethylene (UPE) filter to prepare a composition for forming an imprint pattern and a comparative composition.

TABLE 1

| | | | Example | | | | | | | | | | |
|---|---|---|---|---|---|---|---|---|---|---|---|---|---|
| | | | 1 | 2 | 3 | 4 | 5 | 6 | 7 | 8 | 9 | 10 | 11 |
| Composition | Polymerizable | A-1 | 96.3 | 96.3 | 96.3 | 96.3 | 74 | 96.3 | 96.3 | — | 96.3 | 96.3 | 96.3 |
| for forming | compound | A-2 | — | — | — | — | — | — | — | — | — | — | — |
| imprint | | A-3 | — | — | — | — | — | — | — | — | — | — | — |
| pattern | | A-4 | — | — | — | — | — | — | — | — | — | — | — |
| | | A-5 | — | — | — | — | — | — | — | — | — | — | — |
| | | A-6 | — | — | — | — | — | — | — | 65 | — | — | — |
| | | A-7 | — | — | — | — | — | — | — | 20 | — | — | — |
| | | A-8 | — | — | — | — | — | — | — | 15 | — | — | — |
| | Initiator | B-1 | 3 | 3 | 3 | 3 | 2 | — | 3 | — | 3 | 3 | 3 |
| | | B-2 | — | — | — | — | — | 3 | — | 2 | — | — | — |
| | | B-3 | — | — | — | — | — | — | — | — | — | — | — |
| | | B-4 | — | — | — | — | — | — | — | 2 | — | — | — |
| | Dye | C-1 | 1 | — | — | 0.09 | 23 | — | 1 | 1 | — | — | — |
| | | C-2 | — | — | — | — | — | — | — | — | 1 | — | — |
| | | C-4 | — | — | — | — | — | — | — | — | — | 1 | — |
| | | C-5 | — | — | — | — | — | — | — | — | — | — | 1 |
| | | C-6 | — | — | — | — | — | — | — | — | — | — | — |
| | | C-7 | — | — | — | — | — | — | — | — | — | — | — |
| | | C-8 | — | 1 | — | — | — | — | — | — | — | — | — |
| | | C-9 | — | — | 1 | — | — | 1 | — | — | — | — | — |
| | Release agent | D-1 | 0.8 | 0.8 | 0.8 | 0.8 | 1 | 0.8 | 0.8 | 3 | 0.8 | 0.8 | 0.8 |
| | | D-2 | — | — | — | — | — | — | — | — | — | — | — |
| | Solvent | E-1 | 100 | 100 | 100 | 100 | 100 | 100 | 100 | — | 100 | 100 | 100 |

| | | | | | | | | | | | |
|---|---|---|---|---|---|---|---|---|---|---|---|
| Concentration of solid | 2 | 2 | 2 | 2 | 2 | 2 | 80 | 100 | 2 | 2 | 2 |
| contents (% by mass) | | | | | | | | | | | |
| Applicable method | S | S | S | S | S | S | S | 1 | S | S | S |
| Curing method | A | A | A | A | A | A | A | A | A | A | A |

| | | | | | | | | | | | |
|---|---|---|---|---|---|---|---|---|---|---|---|
| Resin for composition for forming | F-1 | F-1 | F-1 | F-1 | F-1 | F-1 | F-1 | F-1 | F-1 | F-1 | F-1 |
| closely adhesive layer | | | | | | | | | | | |
| Peeling visibility of composition | A | B | B | B | A | A | A | A | A | A | A |
| Mold durability | A | C | A | A | C | C | A | A | B | B | B |
| Repeatable pattern formation | A | B | A | A | B | B | B | A | A | A | A |
| Mold transparency | A | B | A | A | B | B | A | A | A | A | A |

TABLE 2

| | | | | | | | | | | | | | Comparative | |
|---|---|---|---|---|---|---|---|---|---|---|---|---|---|---|
| | | | Example | | | | | | | | | | Example | |
| | | | 12 | 13 | 14 | 15 | 16 | 17 | 18 | 19 | 20 | 21 | 1 | 2 |
| Composition | Polymerizable | A-1 | 96.3 | — | — | — | — | 96.3 | 96.3 | 96.3 | 96.3 | 96.3 | 96.3 | 96.3 |
| for forming | compound | A-2 | — | 96.3 | — | — | — | — | — | — | — | — | — | — |
| imprint | | A-3 | — | — | 96.3 | — | — | — | — | — | — | — | — | — |
| pattern | | A-4 | — | — | — | 96.3 | — | — | — | — | — | — | — | — |
| | | A-5 | — | — | — | — | 96.3 | — | — | — | — | — | — | — |
| | | A-6 | — | — | — | — | — | — | — | — | — | — | — | — |
| | | A-7 | — | — | — | — | — | — | — | — | — | — | — | — |
| | | A-8 | — | — | — | — | — | — | — | — | — | — | — | — |
| | Initiator | B-1 | 3 | 3 | 3 | 3 | 3 | 3 | — | 3 | 3 | 3 | 3 | 3 |
| | | B-2 | — | — | — | — | — | — | — | — | — | — | — | — |
| | | B-3 | — | — | — | — | — | — | 3 | — | — | — | — | — |
| | | B-4 | — | — | — | — | — | — | — | — | — | — | — | — |
| | Dye | C-1 | — | — | — | — | — | — | 1 | 1 | 1 | 1 | — | — |
| | | C-2 | — | — | — | — | — | — | — | — | — | — | — | — |
| | | C-4 | — | — | — | — | — | — | — | — | — | — | — | — |
| | | C-5 | — | — | — | — | — | — | — | — | — | — | — | — |
| | | C-6 | 1 | 1 | 1 | 1 | 1 | 1 | — | — | — | — | — | — |
| | | C-7 | — | — | — | — | — | — | — | — | — | — | — | 1 |
| | | C-8 | — | — | — | — | — | — | — | — | — | — | — | — |
| | | C-9 | — | — | — | — | — | — | — | — | — | — | — | — |
| | Release agent | D-1 | 0.8 | 0.8 | 0.8 | 0.8 | 0.8 | 0.8 | 0.8 | 0.8 | 0.8 | — | 0.8 | 0.8 |
| | | D-2 | — | — | — | — | — | — | — | — | — | 0.8 | — | — |
| | Solvent | E-1 | 100 | 100 | 100 | 100 | 100 | 100 | 100 | 100 | 100 | 100 | 100 | 100 |

| | | | | | | | | | | | | |
|---|---|---|---|---|---|---|---|---|---|---|---|---|
| Concentration of | 2 | 2 | 2 | 2 | 2 | 2 | 2 | 2 | 2 | 2 | 2 | 2 |
| solid contents (% by | | | | | | | | | | | | |
| mass) | | | | | | | | | | | | |
| Applicable method | S | S | S | S | S | S | S | S | S | S | S | S |
| Curing method | A | A | A | A | A | A | B | A | A | A | A | A |

| | | | | | | | | | | | | |
|---|---|---|---|---|---|---|---|---|---|---|---|---|
| Resin for composition for forming | F-1 | F-1 | F-1 | F-1 | F-1 | F-1 | F-1 | F-2 | F-3 | F-1 | F-1 | F-1 |
| closely adhesive layer | | | | | | | | | | | | |
| Peeling visibility of composition | A | A | A | A | A | A | A | A | A | A | C | B |
| Mold durability | A | A | A | A | A | A | A | A | A | A | A | D |
| Repeatable pattern formation | A | A | A | B | B | A | B | A | A | B | A | C |
| Mold transparency | A | A | A | C | C | A | A | A | A | A | A | D |

Details of each of the components listed in Table 1 or Table 2 are as follows.

### Polymerizable Compound

A-1: synthetic product synthesized in Synthesis Example 1 described later

A-2: synthetic product synthesized in Synthesis Example 2 described later

A-3: dendrimer-type polyfunctional acrylate SIRIUS-501 (manufactured by OSAKA ORGANIC CHEMICAL INDUSTRY LTD.)

A-4: ethoxylated bisphenol A diacrylate A-BPE-30 (manufactured by Shin-Nakamura Chemical Co., Ltd.)

A-5: 9,9-bis[4-(2-acryloyloxyethoxy)phenyl]fluorene A-BPLF (manufactured by Shin-Nakamura Chemical Co., Ltd.)

A-6: compound represented by Formula (A-6)

A-7: compound represented by Formula (A-7)

A-8: compound represented by Formula (A-8)

### Synthesis Example 1: Synthesis of Polymerizable Compound A-2

A methyl silicone resin KR-500 (trade name, manufactured by Shin-Etsu Chemical Co., Ltd.) (110.8 parts), 2-hydroxyethyl acrylate (58.1 parts), and paratoluene sulfonic acid monohydrate (0.034 parts) were mixed with each other, and then the mixture was heated at 120° C. and stirred for 3 hours while distilling off methanol produced by a condensation reaction to obtain 153.9 parts of a polymerizable compound A-2.

### Synthesis Example 2: Synthesis of Polymerizable Compound A-1

A polymerizable compound A-1 was obtained by the same method as in Synthesis Example 1, except that, in Synthesis Example 1, the methyl silicone resin KR-500 was changed to the same molar amount of a silicone resin X-40-9225.

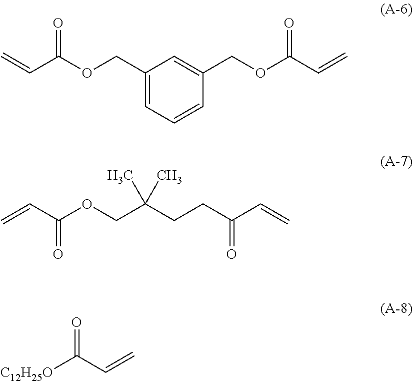

### Initiator (Polymerization Initiator)

B-1: Omnirad 369E (manufactured by IGM Resins B.V.)

B-2: Omnirad 819 (manufactured by IGM Resins B.V.)

B-3: 2,2′-azobis(isobutyronitrile) (manufactured by Tokyo Chemical Industry Co., Ltd.)

B-4: Omnirad 1173 (manufactured by IGM Resins B.V.)

### Dye

C-1 to C-9: compounds listed in Table 3 below

TABLE 3

| Name | C-1 | C-2 | C-4 | C-5 |
|---|---|---|---|---|
| Dye type | Azo-based | Azo-based | Xanthene- | Anthraquinone- |
| | compound | compound | based | based |
| | | | compound | compound |
| Dye | Solvent | solvent | Solvent | Solvent |
| | Yellow 4 | orange 7 | Red 49 | Blue 59 |
| Maximal | 440 | 490 | 542 | 595 |
| absorption | | | | |
| wave- | | | | |
| length | | | | |
| (nm) | | | | |
| Molar | 19000 | 275 | 88000 | 14600 |
| absorption | | | | |
| coefficient | | | | |
| L/ | | | | |
| (mol · cm) | | | | |
| Name | C-6 | C-7 | C-8 | C-9 |
| Dye type | Xanthene- | Copper | Benzotriazole- | Isoindoline- |
| | based | phthalo- | based | based |
| | compound | cyanine- | compound | compound |
| | | based | | |
| | | compound | | |
| Dye | RDW-R60 | Direct | Compound | Diallyl |
| | manufactured | blue 86 | having | azaisoindolyl |
| | by | | structure | methene- |
| | Fujifilm Wako | | represented | based |
| | Pure Chemical | | by Formula | compound |
| | Corporation | | (C-8) | |
| Maximal | 499 | 620 | 354 | 715 |
| absorption | | | | |
| wave- | | | | |
| length | | | | |
| (nm) | | | | |
| Molar | 25800 | 16600 | 15300 | 85100 |
| absorption | | | | |
| coefficient | | | | |
| L/ | | | | |
| (mol · cm) | | | | |

For each dye, a molar absorption coefficient described in the column of Molar absorption coefficient L/(mol·cm) is a value measured by the following method.

### Measurement of Molar Absorption Coefficient and Maximal Absorption Wavelength

Each dye was diluted with acetonitrile, methanol, chloroform, or water to 0.0001 g/mL to prepare four sample solutions.

Each sample solution prepared was filled in a quartz cell (optical path length: 1 cm), and an absorbance and an absorption coefficient were measured with a spectrophotometer. A measurement wavelength range was 400 to 800 nm, a measurement interval was 1 nm, and a sweep rate was 50 nm/min. Details regarding the measurement procedure and the like were based on JIS K0115:2004. Two samples were produced for one level and were respectively measured three times. Six arithmetic mean values in total were adopted as evaluation values.

For each sample, the maximal absorption wavelength (nm) in the sample with the maximum molar absorption coefficient calculated from the above-described evaluation values, the dilution ratio of each sample, and the molecular weight, and the molar absorption coefficient were shown in Table 3 as the maximal absorption wavelength and the molar absorption coefficient of each dye.

Structures of C-1 to C-5 and C-7 to C-9 described above are as follows.
C-7 is a dye including a metal element in the chemical structure.

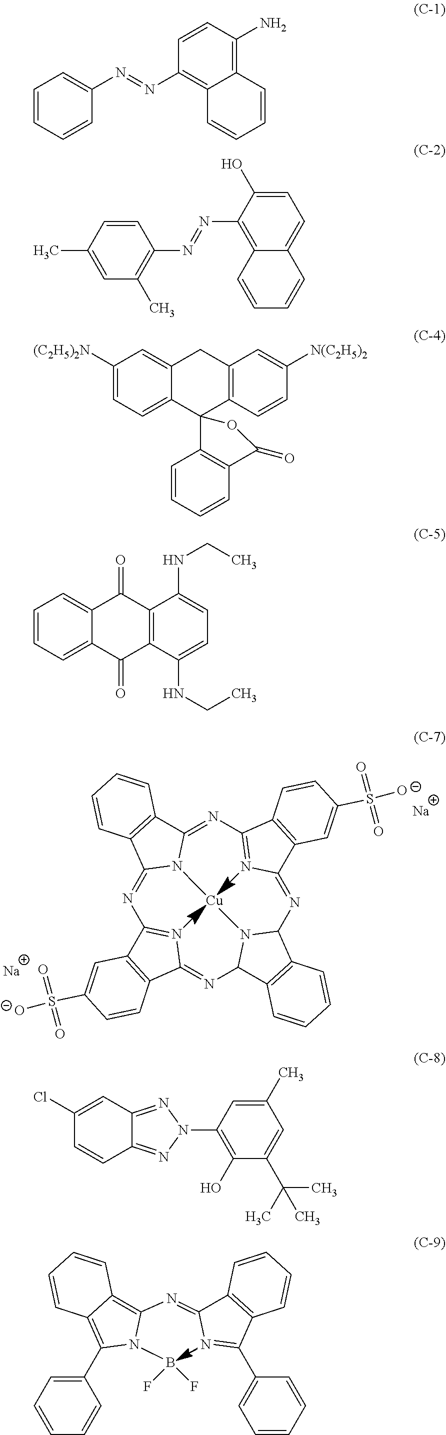

### Release agent

D-1: compound represented by Formula (D-1)

D-2: NONION S-202 (polyoxyethylene-stearyl ether, manufactured by NOF Corporation)

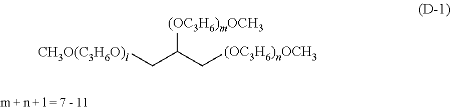

### Solvent

E-1: propylene glycol monomethyl ether acetate (PGMEA)

### Preparation of Composition for Forming Closely Adhesive Layer

For each Example and each Comparative Example, 3 g of the component described in the column of “Resin for composition for forming closely adhesive layer” in Table 1 or Table 2 was dissolved in 997 g of propylene glycol monomethyl ether acetate, and then the mixture was filtered through a 0.1 μm tetrafluoroethylene filter to obtain a composition for forming a closely adhesive layer.

Details of the component described in the column of “Resin for composition for forming closely adhesive layer” in Table 1 or Table 2 are as follows.

F-1: NK OLIGO EA-7140 (manufactured by Shin-Nakamura Chemical Co. Ltd.)

F-2: compound having a structure represented by Formula (F-2)

F-3: compound having a structure represented by Formula (F-3)

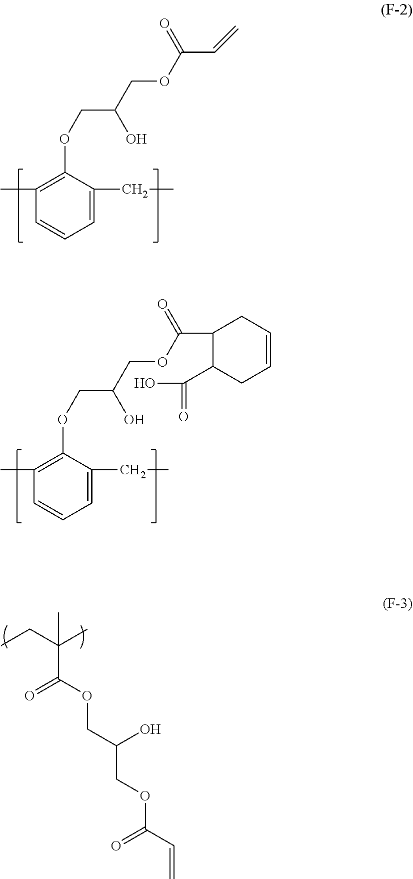

### Evaluation

### Evaluation of Peeling Visibility of Composition

For each Example and each Comparative Example, a silicon wafer was spin-coated with the composition for forming a closely adhesive layer prepared by the above-described method, and heated for 1 minute using a hot plate at 220° C. to form a closely adhesive layer having a thickness of 5 nm.

In an example described as “S” in the column of “Applicable method”, the above-described closely adhesive layer was spin-coated with the composition for forming an imprint pattern or the comparative composition prepared by the above-described method, and heated for 1 minute using a hot plate at 80° C. to obtain a pattern forming layer having a film thickness of 80 nm.

In an example described as “1” in the column of “Applicable method”, the composition for forming an imprint pattern or the comparative composition prepared by the above-described method was applied to the above-described closely adhesive layer using an ink jet device (INK JET PRINTER DMP-2831 manufactured by FUJIFILM Dimatix, Inc.) to obtain a pattern forming layer having a film thickness of 80 nm.

Next, a quartz mold (having a line-and-space pattern with a line width of 20 nm, a depth of 50 nm, and a pitch width of 28 nm) was pressed against the above-described pattern forming layer under a helium atmosphere (replacement rate: 90% or more) to fill the composition for forming an imprint pattern in the quartz mold.

In an example described as “A” in the column of “Curing method”, immediately before a timing of 10 seconds from the above-described pressing, using a high-pressure mercury lamp, exposure was performed from the quartz mold side under the conditions of maximum wavelength of irradiation light source: 365 nm, exposure illuminance: 10 mW/cm², and exposure time: 15 seconds (exposure amount: 150 mJ/cm²), and then the quartz mold was peeled off to transfer a pattern to the pattern forming layer.

In an example described as “B” in the column of “Curing method”, immediately before a timing of 10 seconds from the above-described pressing, the mold and composition were heated at 100° C. for 3 hours while being pressed, and then the quartz mold was peeled off to transfer a pattern to the pattern forming layer.

In this case, it was evaluated according to the following evaluation standard whether the composition for forming an imprint pattern remaining in the quartz mold could be visually recognized. The evaluation results are shown in the column of “Peeling visibility of composition” in Table 1 or Table 2.

### Evaluation Standard

A: it could be visually recognized under a yellow light.

B: it could not be visually recognized under a yellow light, but it could be visually recognized under a white light.

C: it could not be visually recognized under a yellow light and a white light.

### Evaluation of Mold Durability

As a quartz mold, a quartz mold having a line-and-space pattern with a line width of 20 nm, a depth of 50 nm, and a pitch width of 28 nm was used. Coordinates of 500 locations in the quartz mold where defects (mask defects) did not exist were grasped in advance using a mask defect review scanning electron microscope (SEM) device E5610 (manufactured by ADVANTEST CORPORATION).

For Examples and each Comparative Example, a silicon wafer was spin-coated with the composition for forming a closely adhesive film prepared by the above-described method, and heated for 1 minute using a hot plate at 220° C. to form a closely adhesive film having a thickness of 5 nm.

By the same method as the above-described method for evaluating the peeling visibility of the composition, the pattern forming layer was formed on the above-described closely adhesive layer by spin coating or the ink jet device, the pattern was transferred by exposure or heating, and the quartz mold was peeled off.

However, in the transfer of the pattern, in an example described as “A” in the column of “Curing method”, the exposure conditions were set to maximum wavelength of irradiation light source: 365 nm, exposure illuminance: 10 mW/cm², and exposure time: 15 seconds (exposure amount: 150 mJ/cm²).

In addition, in the transfer of the pattern, in an example described as “B” in the column of “Curing method”, the heating conditions were set to 100° C. for 3 hours.

In the evaluation of mold durability, the process from the formation of the above-described closely adhesive film to the release (peeling) of the quartz mold is called as an imprint process.

After repeating the above-described imprint process 100 times using the same quartz mold, the quartz mold was collected, the presence or absence of defects in the quartz mold was confirmed at the above-described 500 locations, and in a case where defects occurred, the number of locations where defects were confirmed was counted. Specifically, among the coordinates of the above-described 500 locations, the number of coordinates having the following rate of change of 3% or greater was defined as the number of locations where defects were confirmed. The evaluation was performed according to the following evaluation standard, and the evaluation results are described in the column of “Mold durability” of Table 1 or Table 2. The evaluation result is preferably A, or C, more preferably A or B, and still more preferably A. It can be said that, as the locations where defects were confirmed are fewer, the mold durability is excellent.

Rate of change (%): {(Height information of quartz mold before being subjected to imprint process)−(Height information of quartz mold after repeating imprint process 100 times)}/((Height information in quartz mold before being subjected to imprint process)×100

### Evaluation Standard

A: no defects in the quartz mold were confirmed.

B: number of locations where defects in the quartz mold were confirmed was 1 or more and less than 5.

C: number of locations where defects in the quartz mold were confirmed was 5 or more and less than 25.

D: number of locations where defects in the quartz mold were confirmed was 25 or more.

### Evaluation of Repeatable Pattern Formation

For each Example and each Comparative Example, a silicon wafer was spin-coated with the composition for forming a closely adhesive layer prepared by the above-described method, and heated for 1 minute using a hot plate at 220° C. to form a closely adhesive layer having a thickness of 5 nm.

By the same method as the above-described method for evaluating the mold durability, the pattern forming layer was formed on the above-described closely adhesive layer by spin coating or the ink jet device, the pattern was transferred by exposure or heating, and the quartz mold was peeled off.

In the evaluation of repeatable pattern formation, the process from the formation of the above-described closely adhesive film to the release of the quartz mold is called as an imprint process.

The above-described imprint process was repeated 100 times using the same quartz mold.

The pattern obtained in the 100th process was observed with a scanning electron microscope (SEM) at a magnification of 10,000 times. The evaluation was performed according to the following evaluation standard, and the evaluation results are described in the column of “Repeatable pattern formation” of Table 1 or Table 2. The evaluation result is preferably A, B, or C, more preferably A or B, and still more preferably A.

### Evaluation Standard

A: good pattern was confirmed over the entire surface.

B: defective pattern was confirmed in a part of the area.

C: defective pattern was confirmed over the entire surface.

### Evaluation of Mold Transparency

As a quartz mold, a quartz mold having a flat surface was used.

Using a spectrophotometer U-4100 (manufactured by Hitachi High-Technologies Corporation), a transmittance (transmittance A, unit: %) of the quartz mold before an imprint test was performed was measured.

Subsequently, a silicon wafer was spin-coated with the composition for forming a closely adhesive layer prepared by the above-described method, and heated for 1 minute using a hot plate at 220° C. to form a closely adhesive layer having a thickness of 5 nm.

By the same method as the above-described method for evaluating the peeling visibility of the composition, except that, as the quartz mold, the quartz mold having a flat surface was used instead of the quartz mold having a line-and-space pattern, the pattern forming layer was formed on the above-described closely adhesive layer by spin coating or the ink jet device, the pattern was transferred by exposure or heating, and the quartz mold was peeled off.

However, in the above-described method for evaluating the peeling visibility of the composition, the description “to fill the composition for forming an imprint pattern in the quartz mold” is read as “to contact the composition for forming an imprint pattern with the flat surface of the quartz mold”.

In the evaluation of mold transparency, the process from the formation of the above-described closely adhesive film to the release of the quartz mold is called as the imprint test.

After repeating the above-described imprint test 100 times using the same quartz mold, the quartz mold was collected, and a transmittance (transmittance B, unit: %) of the quartz mold was measured.

In a wavelength of 400 to 800 nm, a change ΔT in transmittance at a wavelength where the change in transmittance was the largest before and after the imprint test was calculated by the following expression and evaluated. The evaluation was performed according to the following evaluation standard, and the evaluation results are described in the column of “Mold transparency” of Table 1 or Table 2. The evaluation result is preferably A, B, or C, more preferably A or B, and still more preferably A.

ΔT=|Transmittance A−Transmittance B|

### Evaluation Standard

A: 10%≤ΔT

B: 5%≤ΔT≤10%

C: 3%≤ΔT≤5%

C: 0%≤ΔT<3%

From the above results, it is found that, in a case where the composition for forming an imprint pattern according to the embodiment of the present invention is used, the peeling of the composition for forming an imprint pattern from a mold can be visually recognized, and a mold durability is excellent.

The composition according to Comparative Example 1 did not include the dye. In a case where such a composition is used, it is found that the result of peeling visibility of the composition is poor, and the peeling of the composition from the mold cannot be visually recognized.

The composition according to Comparative Example 2 included a compound having a metal element in the chemical structure as the dye. In a case where such a composition is used, it is found that the mold durability is deteriorated.

Moreover, the closely adhesive layer was formed on the silicon wafer using the composition for forming a closely adhesive layer according to each Example, and a predetermined pattern corresponding to a semiconductor circuit was formed on the silicon wafer with the closely adhesive layer using the composition for forming an imprint pattern according to each Example. Moreover, each silicon wafer was dry-etched by using this pattern as an etching mask, and each semiconductor element was manufactured using this silicon wafer. There was no problem with the performance of any of the semiconductor elements. Further, using the composition for forming a closely adhesive layer and composition for forming an imprint pattern of Example 1, a semiconductor element was manufactured on a substrate having a spin-on carbon (SOC) layer by the same procedure as described above. There was no problem with the performance of this semiconductor element as well,

What is claimed is:

1. A composition for forming an imprint pattern comprising:
a polymerizable compound;
a polymerization initiator; and
a dye,
wherein the dye is a compound which has no metal element in a chemical structure.

2. The composition for forming an imprint pattern according to claim 1,
wherein a maximum value of a molar absorption coefficient of the dye in an acetonitrile solution, a methanol solution, a chloroform solution, and an aqueous solution in a wavelength range of 400 to 800 nm is 50 L/(mol·cm) or greater.

3. The composition for forming an imprint pattern according to claim 1,
wherein the dye is a compound which has a maximal absorption in a wavelength range of 400) to 800 nm in at least one of an acetonitrile solution, a methanol solution, a chloroform solution, and an aqueous solution.

4. The composition for forming an imprint pattern according to claim 1,
wherein the dye includes at least one compound selected from the group consisting of an azo-based compound, an anthraquinone-based compound, and a carbonium-based compound.

5. The composition for forming an imprint pattern according to claim 1,
wherein a content of the dye is 0.001% to 20.0% by mass with respect to a total solid content of the composition for forming an imprint pattern.

6. The composition for forming an imprint pattern according to claim 1,
wherein the polymerization initiator is a photopolymerization initiator.

7. The composition for forming an imprint pattern according to claim 1, further comprising:
a release agent.

8. The composition for forming an imprint pattern according to claim 1, further comprising:
a solvent,
wherein a content of the solvent is 90.0% to 99.0% by mass with respect to a total mass of the composition for forming an imprint pattern.

9. The composition for forming an imprint pattern according to claim 1,
wherein the composition for forming an imprint pattern does not include a solvent, or
the composition for forming an imprint pattern includes a solvent and a content of the solvent is greater than 0% by mass and lower than 5% by mass with respect to a total mass of the composition for forming an imprint pattern.

10. The composition for forming an imprint pattern according to claim
wherein a total content of a metal atom and a metal ion is 0.1% by mass or lower with respect to a total solid content of the composition for forming an imprint pattern.

11. The composition for forming an imprint pattern according to claim 1,
wherein a content of an inorganic compound is 1% by mass or lower with respect to a total solid content of the composition for forming an imprint pattern.

12. The composition for forming an imprint pattern according to claim 1,
wherein a content of a salt compound is 1% by mass or lower with respect to a total solid content of the composition for forming an imprint pattern.

13. A cured substance obtained by curing the composition for forming an imprint pattern according to claim 1.

14. An imprint pattern producing method comprising:
an applying step of applying the composition for forming an imprint pattern according to claim 1 to a member to be applied, which is selected from the group consisting of a support and a mold;
a contact step of contacting a member which is not selected as the member to be applied from the group consisting of the support and the mold with the composition for forming an imprint pattern as a contact member;
a curing step of forming a cured substance with the composition for forming an imprint pattern; and
a peeling step of peeling off the cured substance from the mold.

15. The imprint pattern producing method according to claim 14, further comprising:
a step of evaluating a transparency of the mold using a visible light having a wavelength at which the dye has an absorption after the peeling step.

16. The imprint pattern producing method according to claim 14,
wherein the support is a member including a closely adhesive layer on a surface on a side to which the composition for forming an imprint pattern is applied.

17. A method for manufacturing a device, comprising:
the imprint pattern producing method according to claim 14.
